(19) United States
(12) Patent Application Publication
(10) Pub. No.: US 2022/0291359 A1
(43) Pub. Date: Sep. 15, 2022

(54) LiDAR System with Active Fault Monitoring

(71) Applicant: OPSYS Tech Ltd., Holon (IL)

(72) Inventors: Noam Tziony, Petah Tikva (IL); Mark J. Donovan, Mountain View, CA (US)

(73) Assignee: OPSYS Tech Ltd., Holon (IL)

(21) Appl. No.: 17/687,652

(22) Filed: Mar. 6, 2022

Related U.S. Application Data
(60) Provisional application No. 63/158,739, filed on Mar. 9, 2021.

(51) Int. Cl. G01S 7/497; G01S 17/931; G01S 17/894; G01S 17/10; G01S 7/481; G01R 19/165

(52) U.S. Cl. CPC G01S 7/497; G01S 17/931; G01S 17/894; G01S 17/10; G01S 7/4815; G01R 19/16557

(57) ABSTRACT

A method for detecting a fault condition in a light detection and ranging transmitter includes generating a control signal that comprises an address and desired drive voltage and current information for a laser in a laser array. A drive signal is generated for the laser in the laser array in response to the generated control signal and applied to a contact associated with that address of the laser array, thereby energizing the laser at a desired output power for a desired time. A determination is made on whether the drive signal has a parameter with a value that is outside a threshold range for eye safety. The address and the fault condition is stored if the parameter has the value outside the threshold range for eye safety and reported to a host that takes an action on the LiDAR transmitter in response to the fault condition.

### RELATED APPLICATION SECTION

The present application is a non-provisional of U.S. Patent Provisional Patent Application No. 63/158,739, entitled “LiDAR System with Active Fault Monitoring”, filed on Mar. 9, 2021. The entire contents of U.S. Patent Provisional Patent Application No. 63/158,739 are herein incorporated by reference.

The section headings used herein are for organizational purposes only and should not to be construed as limiting the subject matter described in the present application in any way.

### INTRODUCTION

Autonomous, self-driving, and semi-autonomous automobiles use a combination of different sensors and technologies such as radar, image-recognition cameras, and sonar for detection and location of surrounding objects. These sensors enable a host of improvements in driver safety including collision warning, automatic-emergency braking, lane-departure warning, lane-keeping assistance, adaptive cruise control, and piloted driving. Among these sensor technologies, light detection and ranging (LiDAR) systems take a critical role, enabling real-time, high-resolution 3D mapping of the surrounding environment.

Most current LiDAR systems used for autonomous vehicles today utilize a small number of lasers, combined with some method of mechanically scanning the environment. Some state-of-the-art LiDAR systems use two-dimensional Vertical Cavity Surface Emitting Lasers (VCSEL) arrays as the illumination source and various types of solid-state detector arrays in the receiver. It is highly desired that future autonomous cars utilize solid-state semiconductor-based LiDAR systems with high reliability and wide environmental operating ranges. These solid-state LiDAR systems are advantageous because they use solid state technology that has no moving parts. However, currently state-of-the-art LiDAR systems have many practical limitations and new systems and methods are needed to improve performance, safety, reliability and user experience.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale; emphasis instead generally being placed upon illustrating principles of the teaching. The drawings are not intended to limit the scope of the Applicant's teaching in any way.

FIG. 1 illustrates an embodiment of a LiDAR system of the present teaching implemented in a vehicle.

FIG. 2A illustrates a block diagram of an embodiment of a monitored system that includes a LiDAR transmitter and receiver system connected to a host processor of the present teaching.

FIG. 2B illustrates a block diagram of an embodiment of a monitored LiDAR transmitter and receiver system with a transmit subassembly illuminating a target of the present teaching.

FIG. 2C illustrates an expanded view of the transmit subassembly of FIG. 2B.

FIG. 2D illustrates an expanded view of a high-side current pulse embodiment of a transmit subassembly of the present teaching.

FIG. 2E illustrates an expanded view of low-side current pulse embodiment of a transmit subassembly of the present teaching.

FIG. 2F illustrates example failure modes for the optical power as a function of time relating to eye safety for embodiments of a monitored LiDAR transmitter of the present teaching.

FIG. 3 illustrates an embodiment of the transmit electronics of the LiDAR transmit and receive system of FIG. 2A.

FIG. 4 illustrates an embodiment of the diagnostics module of the embodiment of the transmit electronics of FIG. 3.

FIG. 5A illustrates an embodiment of a transmit subassembly for a VCSEL array for a monitored LiDAR transmitter of the present teaching.

FIG. 5B illustrates an embodiment of a transmit subassembly for a VCSEL array for a monitored LiDAR transmitter with a shared diagnostics circuit for the low side and high side driver of the present teaching.

FIG. 5C illustrates an embodiment of a transmit subassembly for a VCSEL array for a monitored LiDAR transmitter with a separate diagnostics circuit for the low side and high side driver of the present teaching.

FIG. 6 illustrates a table showing example embodiments of fault criteria, faults and controller reactions for idle operation for a monitored LiDAR system of the present teaching.

FIG. 7 illustrates a table showing example embodiments of fault criteria, faults and controller reactions for active operation at high-side drive for a monitored LiDAR system of the present teaching.

FIG. 8A illustrates graphs that show the time dependence of good active and inactive channels and high threshold at anodes for a monitored LiDAR system of the present teaching.

FIG. 8B illustrates graphs that show the time dependence of bad active and inactive channels and high threshold at anodes for a monitored LiDAR system of the present teaching.

FIG. 9 illustrates a table showing example embodiments of fault criteria, faults and controller reactions for low voltage threshold at anodes for a monitored LiDAR system of the present teaching.

FIG. 10A illustrates graphs that show the time dependence of good active and inactive channels and threshold at a low voltage threshold at anodes for a monitored LiDAR system of the present teaching.

FIG. 10B illustrates graphs that show the time dependence of a bad inactive channel and threshold at a low voltage threshold at anodes for a monitored LiDAR system of the present teaching.

FIG. 11 illustrates a table showing example embodiments of fault criteria, faults and controller reactions for active channels at a low voltage threshold at cathodes for a monitored LiDAR system of the present teaching.

FIG. 12A illustrates graphs that show the time dependence of good active and inactive channels and threshold at a low voltage threshold at cathodes for a monitored LiDAR system of the present teaching.

FIG. 12B illustrates graphs that show the time dependence of a bad active and inactive channels and threshold at a low voltage threshold at cathodes for a monitored LiDAR system of the present teaching.

FIG. 13 illustrates a table showing example embodiments of fault criteria, faults and controller reactions for active channels at a high voltage threshold for cathodes for a monitored LiDAR system of the present teaching.

FIG. 14A illustrates graphs that show the time dependence of good active and inactive channels and threshold at a high voltage threshold at cathodes for a monitored LiDAR system of the present teaching.

FIG. 14B illustrates graphs that show the time dependence of a bad inactive channel and threshold at a high voltage threshold at cathodes for a monitored LiDAR system of the present teaching.

FIG. 15 illustrates a table showing example embodiments of faults and controller reactions relating to monitored pulse width for a monitored LiDAR system of the present teaching.

FIG. 16 illustrates graphs that show the time dependence of a pulse in a high-side drive at anodes for a monitored LiDAR system of the present teaching.

FIG. 17 illustrates a timing diagram for the high-side and low-side drive and optical pulses of an embodiment of the monitored LiDAR system of the present teaching.

### DESCRIPTION OF VARIOUS EMBODIMENTS

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the method of the present teaching can be performed in any order and/or simultaneously as long as the teaching remains operable. Furthermore, it should be understood that the apparatus and method of the present teaching can include any number or all of the described embodiments as long as the teaching remains operable.

The present teaching relates generally to Light Detection and Ranging (LiDAR), which is a remote sensing method that uses laser light to measure distances (ranges) to objects. LiDAR systems generally measure distances to various objects or targets that reflect and/or scatter light. Autonomous vehicles make use of LiDAR systems to generate a highly accurate 3D map of the surrounding environment with fine resolution. The systems and methods described herein are directed towards providing a solid-state, pulsed time-of-flight (TOF) LiDAR system with high levels of reliability, while also maintaining long measurement range as well as low cost.

The present teaching describes various embodiments of a LiDAR system that can monitor and detect faults that affect the transmitter operation, and can take action based on fault conditions to provide improved safety, reliability and usability of the system. The system and method described provides for improved monitoring of faults within a LiDAR system along with methods and algorithms for adapting to those faults. These features provide significant improvements in system safety and product operation.

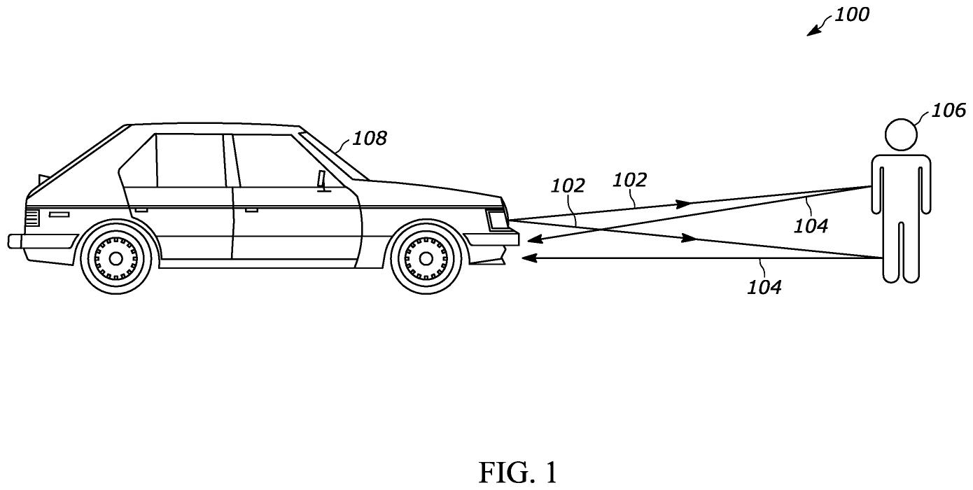

FIG. 1 illustrates a LiDAR system 100 of the present teaching implemented in a vehicle. The LiDAR system 100 includes a laser projector 101, also referred to as an illuminator, that projects light beams 102 generated by a light source toward a target scene and a receiver that receives the light 104 that reflects from an object, shown as a person 106, in that target scene. In some embodiments, the illuminator comprises a laser transmitter and various transmit optics.

LiDAR systems typically also include a controller that computes the distance information about the object 106, which is shown as a person in the figure, from the reflected light. In some embodiments, there is also an element that can scan or otherwise provide a particular pattern of the light that may be a static pattern, or a dynamic pattern across a desired range and field-of-view (FOV). A portion of the reflected light from the object 106 is received by a receiver. In some embodiments, a receiver comprises receive optics and a detector element that can be an array of detectors. The receiver and controller are used to convert the received signal light into measurements that represent a pointwise 3D map of the surrounding environment that falls within the LiDAR system range and FOV.

Some embodiments of LiDAR systems according to the present teaching use a laser transmitter that is a laser array. In some specific embodiments, the laser array comprises VCSEL laser devices. These may include top-emitting VCSELs, bottom-emitting VCSELs, external cavity VCSELs, as well as various types of high-power VCSELs. The VCSEL arrays may be monolithic. The laser emitters may all share a common substrate, including semiconductor substrates or ceramic substrates.

In some embodiments, individual lasers and/or groups of lasers in embodiments that use one or more transmitter arrays can be individually controlled. Each individual emitter in the transmitter array can be fired independently, with the optical beam emitted by each laser emitter corresponding to a 3D projection angle subtending only a portion of the total system field-of-view. One example of such a LiDAR system is described in U.S. Patent Publication No. 2017/0307736 A1, which is assigned to the present assignee. The entire contents of U.S. Patent Publication No. 2017/0307736 A1 are incorporated herein by reference. In addition, the number of pulses fired by an individual laser, or group of lasers can be controlled based on a desired performance objective of the LiDAR system. The duration and timing of this sequence can also be controlled to achieve various performance goals.

One feature of the present teaching is to provide a monitored LiDAR system which can detect faults affecting the transmitter operation and, in some situations, take corrective action based on these fault conditions to provide improved safety, reliability and usability of the LiDAR alone or within a larger sensor system of which the LiDAR is a part. In some sensor systems, the LiDAR is connected to a host processor that manages higher-level sensor functions and system actions and responses. In some sensor systems, the LiDAR is connected to a host processor that manages the LiDAR sensor as a stand-alone sensor system. One feature of the present teaching is that it provides a monitoring capability that can be located near the transmit assembly and/or subassembly hardware and so is able to monitor, identify and/or respond to fault conditions at touch points that are close to the laser devices that generate the emitted light in the transmitter. This approach provides numerous advantages. For example, response times can be faster and/or the cost and complexity of the components needed to find and react to faults can be reduced. Identification of faults can be fast and/or pre-emptive. Reactions to faults can be made during operations. Actions in response to faults can be taken on parts of the system, allowing other parts of the system to sustain operations, resulting, for example, in graceful degradation rather than abrupt failure. With local processing, decisions to transmit and/or escalate reaction to faults to higher-level operating systems can reduce the burden on the operating system and improve system reliability as a whole. The above are just examples of the benefits of the monitored LiDAR transmitter system and method of the present teaching.

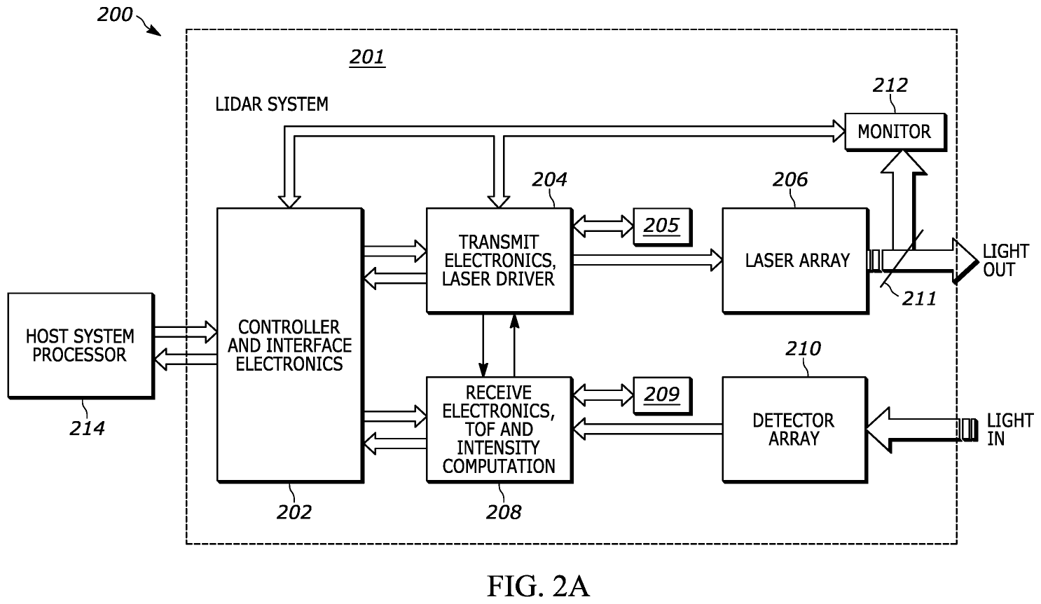

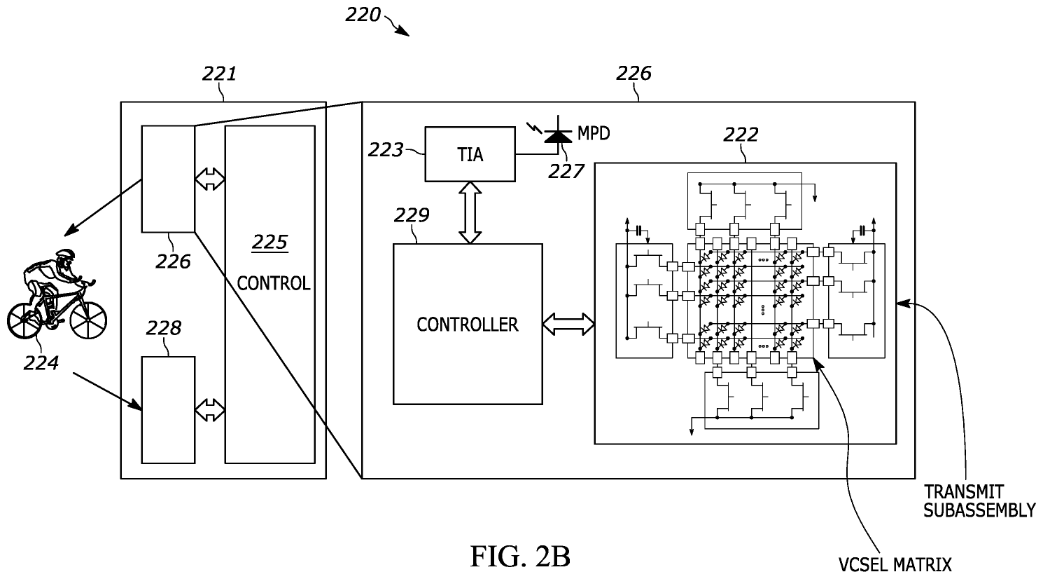

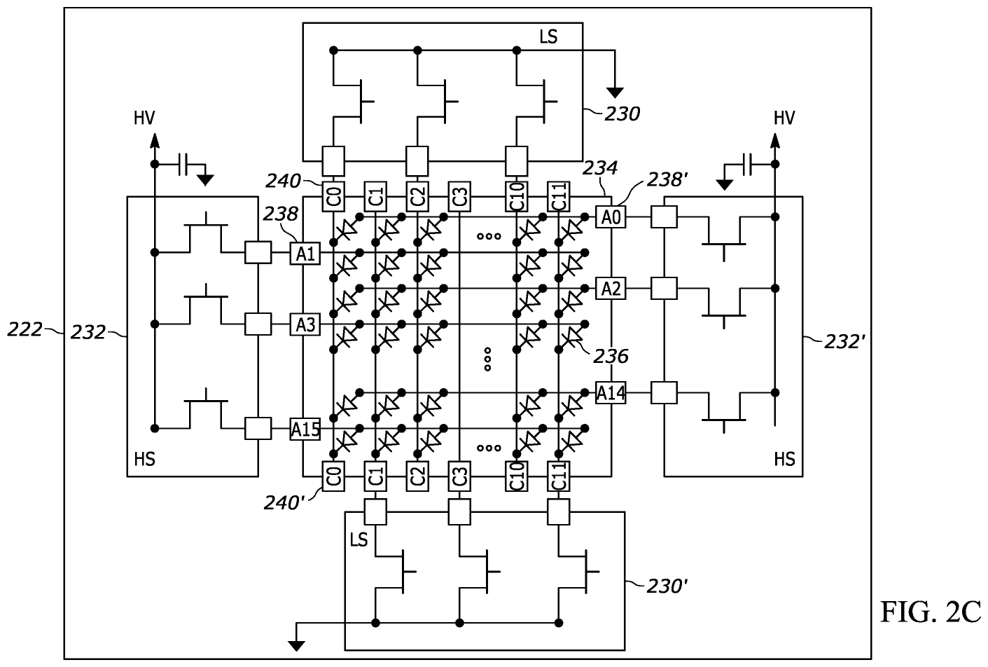

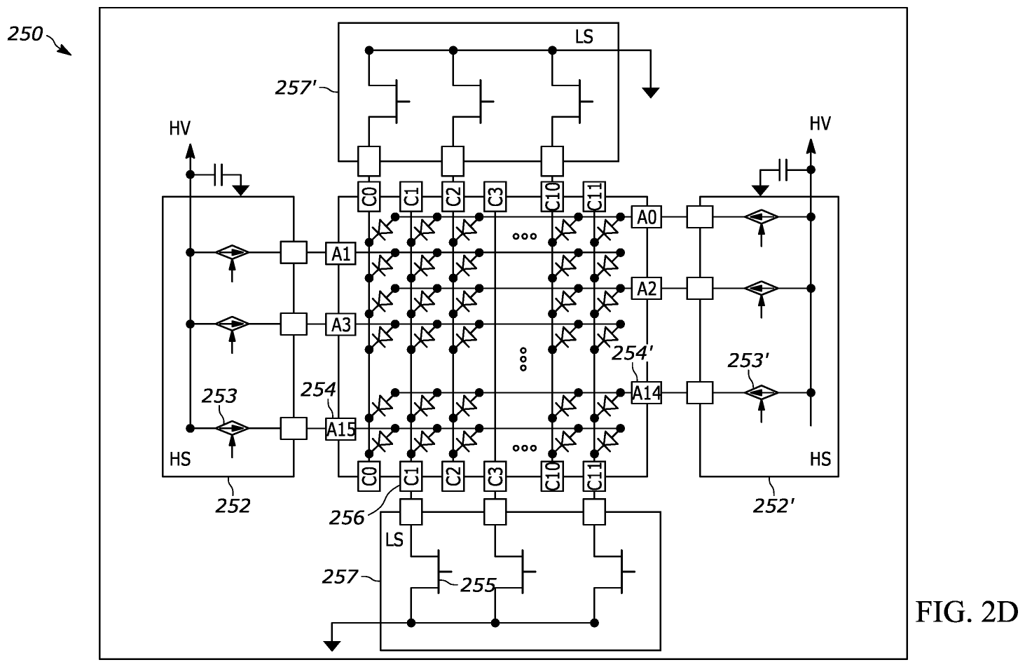

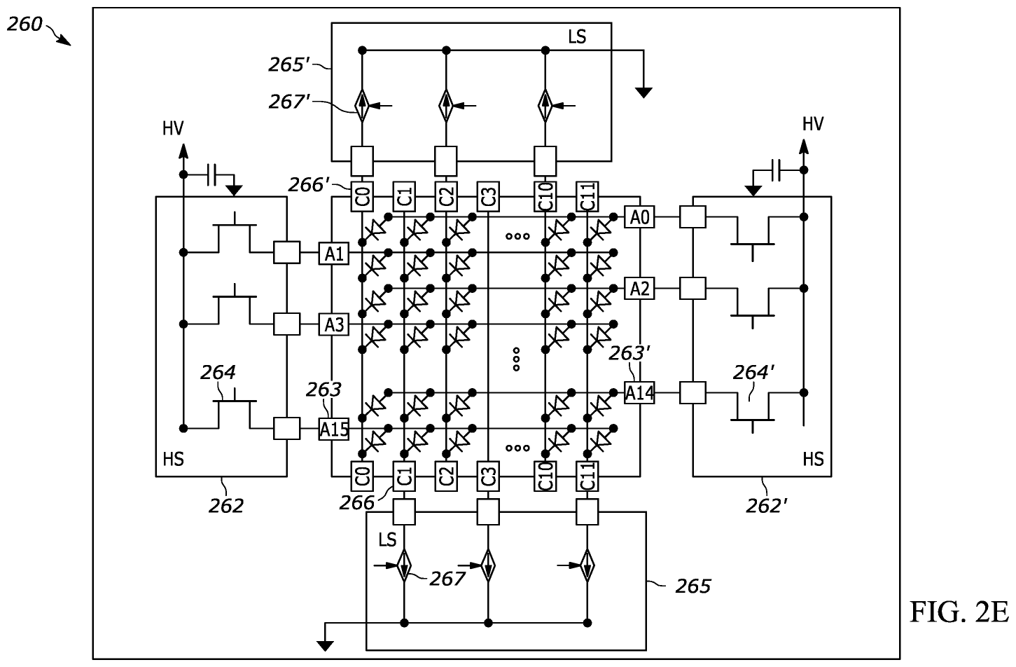

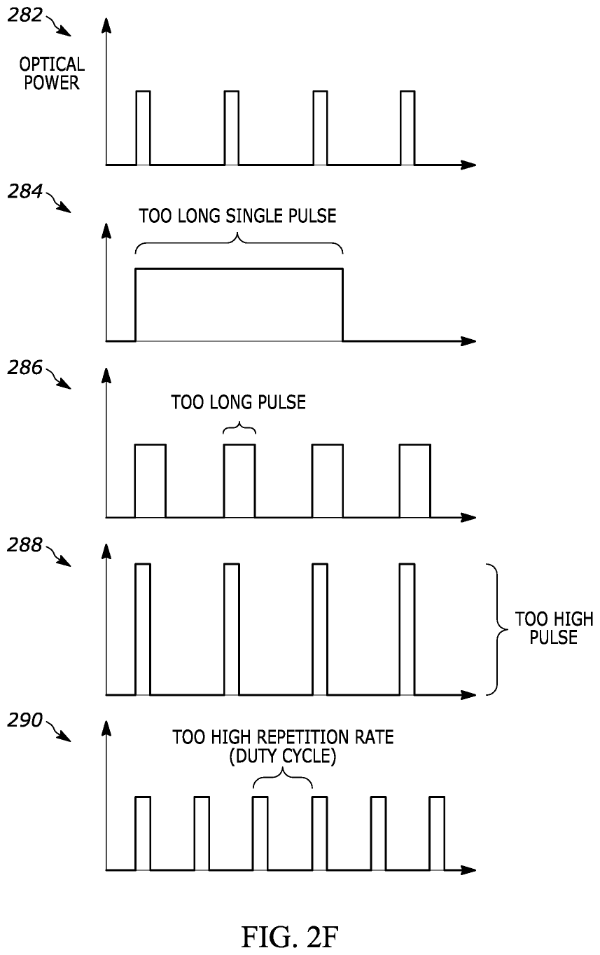

One feature of monitored LiDAR systems of the present teaching is that they can provide synthesized fault information to a host system such that the host system can respond and react in an efficient and effective matter. FIG. 2A illustrates a block diagram of an embodiment of a monitored system 200 that includes a LiDAR transmitter and receiver system 201 connected to a host processor 214 of the present teaching. The LiDAR transmitter and receiver system (LiDAR system) 201 connected to the host processor 214 has six main components: (1) controller and interface electronics 202; (2) transmit electronics 204 including the laser driver; (3) the laser array 206; (4) receive and time-of-flight and intensity computation electronics 208; (5) detector array 210; and (6) in some embodiments an optical monitor 212. The LiDAR system controller and interface electronics 202 controls the overall function of the LiDAR system 201 and provides the digital communication to the host system processor 214. The transmit electronics 204 controls the operation of the laser array 206 and, in some embodiments, sets the pattern and/or power of laser firing of individual elements in the array 206. The receive and time-of-flight computation electronics 208 receives the electrical detection signals from the detector array 210 and then processes these electrical detection signals to compute the range distance through time-of-flight calculations. The intensity of the return signal is also computed in electronics 208.

Optional temperature sensors 205, 209 can also be used for transmitter and/or receiver control and operation. A transmit temperature sensor 205 can be placed close to the laser array 206. The transmit temperature sensor 205 output is electrically connected to the transmit electronics 204. A receive temperature sensor 209 can be placed close to the detector array 210 with an output that is electrically connected to the receive electronics 208. The temperature sensors 205, 209 can provide various thermal monitoring to the electronics 204, 208 and other controllers in the monitored system 200 (connections not shown). For example, a fault condition at the laser array 206 can cause excess power dissipation which will result in a temperature difference between a system temperature sensor (not shown) that is typically positioned some distance away from the array and the laser array temperature sensor 205. The identification of this thermal gradient can cause the transmit controller 204 to stop the firing of lasers in the array 206. For example, various laser array 206 over-temperature or under-temperature conditions that are identified using the temperature sensor 205 will cause the transmit controller 204 to halt firing. These conditions may be absolute temperature conditions, or they may be conditions based on other temperature conditions internal to and/or external to the system 200. Similar identification of, and reaction to, over- and/or under-temperature function is provided for the detector array 210 using the receiver temperature sensor 209.

In some embodiments, the transmit controller 204 reduces the optical power by reducing the pulse current and/or by reducing the pulse duty-cycle to overcome a moderate over-temperature condition. In some embodiments, the transmit controller 204 controls pulse parameters, such as the pulse amplitude, the pulse width, and/or the pulse delay. In some embodiments, the transmit controller 204 will tune the pulse amplitude, the pulse width, and/or the pulse delay to compensate for the drivers' thermal dependency. Also, in some embodiments, the transmit controller 204 will tune the pulse amplitude, the pulse width, and/or the pulse delay to compensate for the temperature dependency of the laser array 206. For example, during a cold-start, the transmit controller 204 can drive the laser array 206 to perform laser firing to heat-up the system, which can be managed by input from the temperature sensor 205. In some embodiments, the transmit controller 204 can capture the data from the temperature sensor 205 to find temperature changes that are sufficiently large to cause thermal shock that can cause cracks or other failures in the optical and/or electronic components in the system 201.

FIG. 2B illustrates a diagram of a sensor system 220 including an embodiment of a monitored LiDAR transmitter and receiver system 221 with a transmit subassembly 222 illuminating a target 224 of the present teaching. In this example, the target 224 is a bicycle with a rider, and serves to underscore the importance of the eye safety requirements of the monitored LiDAR transmitter and receiver system 221. The LiDAR transmitter and receiver system 221 has a transmit assembly 226 and a receive assembly 228 that are connected to a LiDAR system control processor 225. The expanded view block diagram of the transmit assembly 226 shows a monitor photo-diode 227 connected to a trans-impedance amplifier 223 and to a transmit controller 229. It is important to note that both analog and digital signals can pass between the controller 229 and the monitor photodiode 227. A transmit controller 229 is connected to the transmit subassembly 222 that is described in more detail below.

Various embodiments of monitored LiDAR systems described herein include reference to various controllers. The various controllers control different aspects of the system as described. It should be understood that the description of the controllers in no way limits the implementation. The placement of any particular control function in the sensor system and/or the monitored LiDAR system can be flexible based on various performance, size, manufacturing, cost and other constraints of a particular implementation. It should be understood that the controllers described herein may, in whole or in part, be implemented utilizing the same or different electrical components, processors and/or circuits depending on the configuration of the system unless explicitly stated in the description of a particular embodiment.

FIG. 2C illustrates an expanded view of the transmit subassembly 222 of FIG. 2B. The transmit subassembly includes a low-side driver 230 on a top edge of a substrate 234 that holds an array of VCSEL laser elements 236. A second low-side driver 230′ is positioned at the bottom edge of the substrate 234. The low-side drivers 230, 230′ each generate a voltage drive signal in response to a control signal that is appropriate to energize a laser via a cathode electrode connected to the laser emitter or group of emitters. An address of the control signal directs which particular cathode electrode, and as a result, which laser emitter or group of emitters, is energized by a low-side drive signal. A high-side driver 232 is positioned at a left side edge of the substrate 234, and a second high-side driver 232′ is positioned at the right side edge of the substrate. The high-side drivers 232, 232′ generate a voltage drive signal in response to a control signal that is appropriate to energize a laser via an anode electrode connected to the laser emitter or group of laser emitters.

An address of the control signal directs which particular anode electrode, and as a result which laser emitter or group of emitters, is energized by a high-side drive signal. This particular substrate 234 has sixteen anode contacts 238 (only three are pictured) on the left edge of the substrate 234, and sixteen anode contacts 238′ (only three are pictured) on the right edge of the substrate 234. Similarly, there are cathode contacts 240, 240′ positioned on the top and bottom edges of the substrate 234. Each of the laser elements 236 has a connection to an anode contact and a cathode contact. A particular row of laser elements is commonly connected to either a left-side high-side driver 232 via an anode contact 238 or a right-side high side driver 232′ via an anode contact 238′. A particular column of laser elements is commonly connected to either a top-side low-side driver 230 via a cathode contact 240 or a bottom-side low-side driver 230′ via a cathode contact 240′. It should be understood that numerous other connection patterns are possible. This particular connection pattern is configured such that an individual laser element 236 can be energized by providing a drive signal to the high-side and low-side driver to which that laser is connected. The association of the anode and cathode contact that is energized and connected to a laser position, or group of laser emitter positions, is given an address.

FIG. 2D illustrates an expanded view of a high-side current-pulse embodiment of a transmit subassembly 250 of the present teaching. The transmit subassembly 250 includes high-side drivers 252, 252′ that include current pulse generators 253, 253′ that connect the high voltage to the anode contacts 254, 254′. The current pulse generators 253, 253′ are positioned in place of the transistor switches 255 that connect the ground to the cathode contacts 256 in the low side driver 257. In this embodiment of the transmit subassembly 250, the low-side drivers 257, 257′ switch a desired column of laser diode cathodes to ground using the transistor switches 255. The high-side drivers 252, 252′ drive an appropriate current pulse to the anode of a selected row. The row-column selection(s) are based on an address and the current is based on a desired drive level and/or pulse shape. In some embodiments, the current pulse generators 253, 253′ generate current limited pulses to the anodes. The operation of the low-side drivers 257, 257′ is similar to the operation of the low side drivers 230, 230′ described in connection to the transmit subassembly 222 of FIG. 2C. The high-side drivers 232, 232′ of transmit subassembly 222 also operate as switches, or selectors, and do not provide the current limited pulses provided by the high-side drivers 252, 252′ of transmit subassembly 251 embodiment of FIG. 2D. It is also possible to put current drivers on the low side.

FIG. 2E illustrates an expanded view of a low-side current pulse embodiment of a transmit subassembly 260 of the present teaching. The high-side drivers 262, 262′ connect to anode contacts 263, 263′ using transistor switches 264, 264′. Thus, the laser row connected to the high-side voltage is selected based on row address of the appropriate connection, as with the switch-based versions of the drivers in, for example, FIG. 2C. The low-side drivers 265, 265′ connect to the cathode contacts 266, 266′ using current pulse generators 267, 267′ that can be current limited pulse drivers. Thus, the current drive to a column is controlled by an address that selects the column. Also the current pulse to the column can be set by a drive controller (not shown) that is connected to the low-side driver(s) 265, 265′.

The number of drivers, contacts and/or laser emitter elements is not limited to that shown in various embodiments described herein. In general, much larger arrays and numbers of elements are used in practice to construct a state-of-the-art system. Also, the descriptions presented herein generally reference two-dimensional arrays of elements, but it should be understood that the teaching is not so limited and features can also apply to one-dimensional emitter arrays, single emitters, and groups of emitters that are not formed in an array as understood by those skilled in the art.

FIG. 2F illustrates example embodiments of failure modes for the optical power as a function of time relating to eye safety for a monitored LiDAR transmitter of the present teaching. A desired optical power as a function of time is shown in the first trace 282. To achieve the maximum performance, LiDAR systems typically operate very close to the eye safety threshold, and therefore, deviations from the operating point can result in exceeding the safety threshold. System-level eye safety is given by two standards. The IEC 60825 Eye safety class 1, ANSI Z136.1 and FDA/CDRH 21 CFR 1040, in the USA. These safety limits relate to an optical energy of a pulse that enters the eye. As such, both the pulse duration (width), repetition rate, and the pulse peak power factor into the eye safety threshold determination.

A common eye safety failure to consider is a single pulse being too long, which is shown in the second trace 284. The third trace 286 shows multiple pulses in a repetitive pattern that are too long. Another common eye safety failure to consider is pulses having excessive peak power. The fourth trace 288 shows pulses with too much peak power. Yet another common eye safety failure to consider is too high of a repetition rate (or duty cycle). The fifth trace 290 shows pulses with too high of a repetition rate. All these eye-safety failures will result in more energy per period of time than the desired optical power in the first trace 282. These failures in increased pulse duration and/or increased repetition rate can be detected using a time-to-digital converter as described further below.

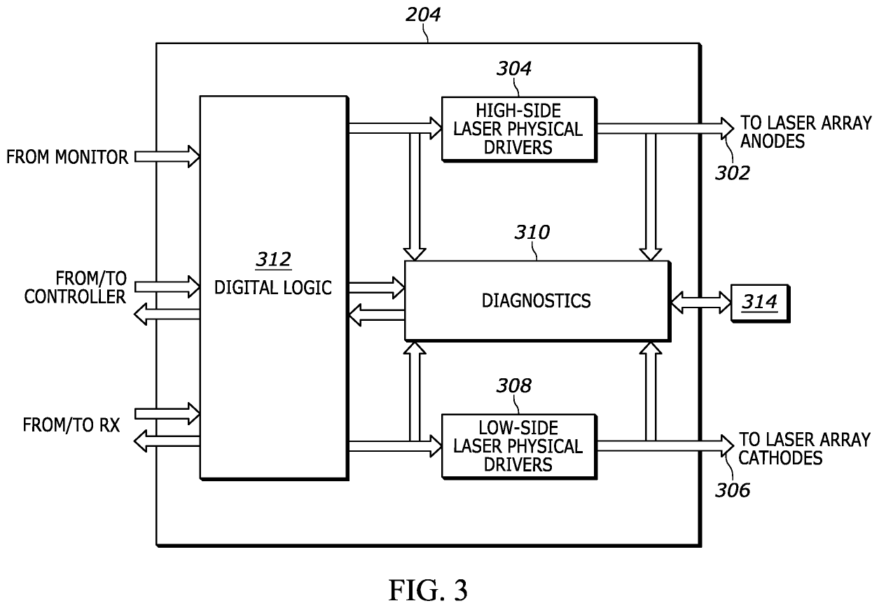

FIG. 3 illustrates an embodiment of the transmit electronics 204 of the LiDAR transmit and receive system described in connection with FIG. 2A. The transmit electronics provides a parallel set of connections 302 from a high-side laser driver 304 to individual laser array anode contacts. The anode contacts connect to particular groups of emitters, depending on the design. The transmit electronics provides a parallel set of connections 306 from a low-side laser driver 308 to laser array cathode contacts. The cathode contacts connect to particular groups of emitters, depending on the design. The outputs of the high-side laser driver 304 and the low-side laser driver 308 are also connected to a diagnostics module 310. A digital logic circuit 312 provides control signals to the high-side laser driver 304 and/or the low-side laser driver 308 that includes an address of a laser or group of emitters in the array to fire and a desired drive voltage to apply to the contact associated with that address. The digital logic 312 also provides this information to the diagnostics module 310. The digital logic 312 receives inputs from a monitor (optional), and provides inputs and outputs to a controller. The controller can be, for example, the controller 202 described in connection with FIG. 2A. The digital logic 312 is also connected via inputs and outputs to a receiver module. The receiver module may be, for example, receiver module 208 described in connection with FIG. 2A.

It should be understood that the digital logic circuit 312 can also contain analog circuits and can provide analog signal inputs and outputs. For example, a monitor photodiode, which is generally configured as an analog device, can interface with the digital logic circuit 312. It should be understood that the term “digital logic” used in connection with the monitoring system of the present teaching includes implementations of simple, low-cost circuits, logic elements, and comparators that provide fast, and accurate identification and reaction to fault conditions.

An optional temperature sensor 314 with a thermal sensor can be placed in proximity to a laser array. The output of the temperature sensor 314 connects to the diagnostics module 310. In some embodiments, the temperature sensor 314 can be part of the high-side and/or low side drivers. For example, this includes any or all of drivers 230, 230′, 232, 232′, 252, 252′, 257, 257′, 262, 262′, 265, 265′ shown in FIGS. 2C-E.

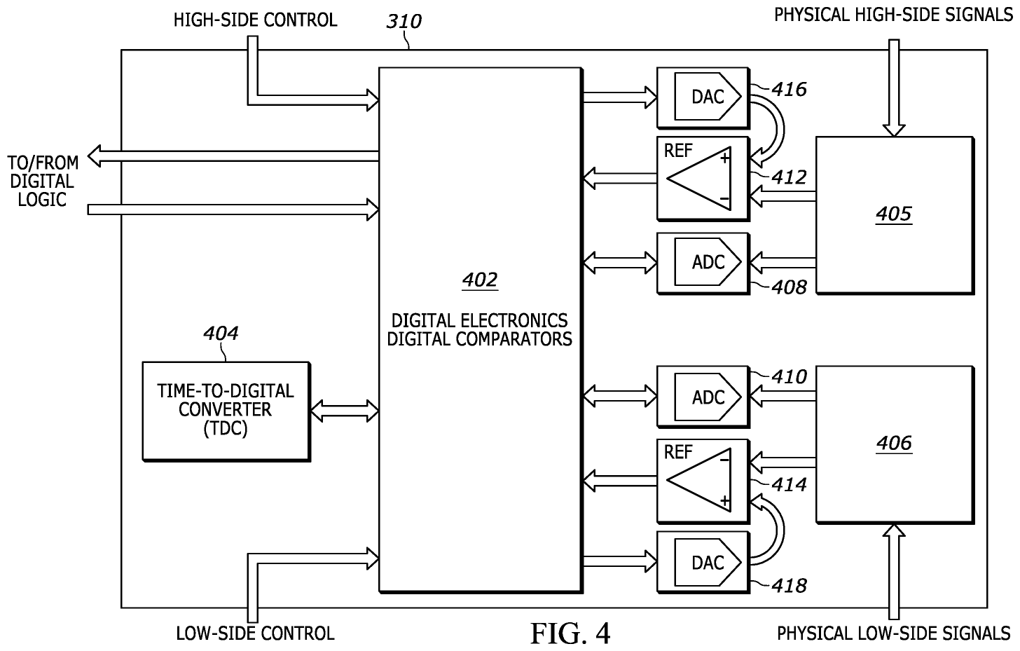

FIG. 4 illustrates an embodiment of the diagnostics module 310 of the embodiment of the transmit electronics 204 described in connection with FIG. 3. Digital electronics 402 are fed input signals from the high-side control and low-side control that include an address and desired drive voltage levels that are provided by the digital logic circuit 312 described in connection with FIG. 3. There is also input and output to the digital logic circuit 312 for transmission of other signals between the digital electronics 402 and digital logic circuit 312.

The digital electronics 402 can include digital comparators. A time-to-digital converter (TDC) 404 is connected to the digital electronics 402. The TDC 404 is able to provide information on pulse duration, and/or repetition rate of both the desired laser drive voltages (or currents) for the high-side and for the low-side as well as the actual high-side and low-side drive voltages (or currents) that are provided to the laser and to the digital electronics 402. In this way, simple logic operations performed by the digital electronics 402 can provide fault information relating to meeting eye safety requirements as described herein.

The physical high-side signal drive voltages (parallel lines) and the physical low-side signal drive voltages (or currents) (parallel lines) are passed through electrical circuits 405, 406 that may be voltage attenuators and/or current monitors and to an analog-to-digital converter (ADC) 408, 410 and to one input side of a comparator 412, 414. In embodiments that use current monitoring in the electrical circuits 405, 406 that pass the physical signal drive currents, the ADC 408, 410 samples a peak current using a sample and hold. The current monitor electrical circuits 405, 406 can be current mirror circuits.

The comparators 412, 414 are analog comparators. In some embodiments, the ADC 408, 410 are multi-channel low-speed ADCs. In some embodiments, a comparator 412, 414 is a multichannel comparator. A second input of the comparators 412, 414 is provided an analog voltage by a digital-to-analog converters (DACs) 416, 418 that is connected to the digital electronics 402. In some embodiments the ADCs 408, 410 are multi-channel low-speed ADCs. The digital-to-analog converter 416, 418 provides a threshold voltage to be compared in the comparator 412, 414. In this configuration of the diagnostics module 310, simple logic operations in the digital electronics 402 using the output of the comparator 412, 414 and/or ADC 408, 410 can detect and provide fault indicators to the digital logic 312 (FIG. 3) for various faults. Example faults include: a shorted VCSEL in an array matrix, excess VCSEL leakage current, too low VCSEL reverse breakdown voltage, a high-side channel (anode) stuck at a high voltage, a high-side channel (anode) being driven by more than the desired voltage set by the digital logic 312, a low-side channel (cathode) stuck at ground, a low-side channel (cathode) less than the desired voltage set by the digital logic 312.

Another feature of the present teaching is that it can be used with different architectures and/or implementations of high-side and/or low-side drivers connected to the matrix-driven VCSEL array. In addition, high-side-only and low-side-only configurations can be used. Drivers can be positioned on one side, or on both sides of a VCSEL array.

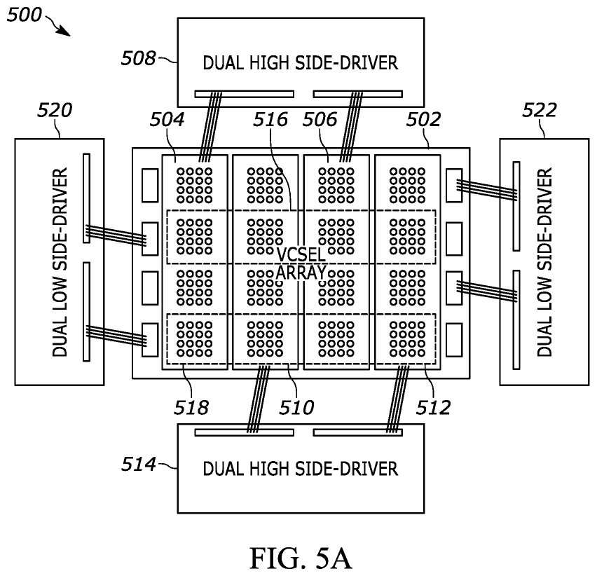

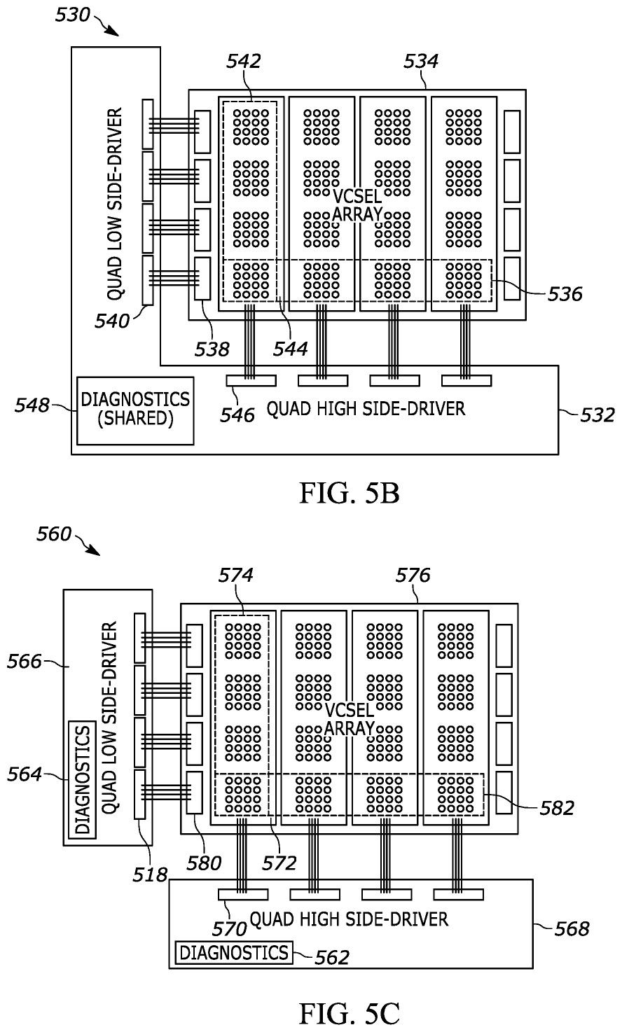

FIG. 5A illustrates an embodiment of a transmit subassembly for a VCSEL array for a monitored LiDAR transmitter of the present teaching. A VCSEL array 502 has columns of laser emitters 504, 506 with anodes connected to a high-side driver 508 positioned on the top side of the array 502, and other columns of laser emitters 510, 512 connected to a high-side driver 514 positioned on the bottom side of the array 502. The VCSEL array 502 has rows of laser emitters 516, 518 with cathodes connected to low-side drivers 520 positioned on the left side of the array 502. Other rows of emitter cathodes are connected to low-side drivers 522 on the right side of the array 502. A two-by-two configuration for the drivers 508, 514, 522, 522 is shown for simplicity, but both much larger and generalized N×M configurations can be used.

In some embodiments, driver chips that comprise the high- and low-side drivers 508, 514, 520, 522 are placed as close as possible to the VCSEL array 502 for low inductance and good electrical performance. The close proximity of the drivers 508, 514, 520, 522 and the array 502 can also enhance the ground return paths under the matrix array 502.

Referring back to FIG. 4, in some embodiments, the diagnostics module 310 is physically part of the same chip as the analog driver circuits of the high- and low-side drivers 508, 514, 520, 522.

Another feature of the present teaching is that various processing electronics and control functions can be shared if desired. FIG. 5B illustrates an embodiment of a transmit subassembly 530 for a VCSEL array 534 for a monitored LiDAR transmitter with a shared integrated circuit chip 532 for the low side and high side driver of the present teaching. The VCSEL array 534 has four rows 536 of emitters that each are connected to a common cathode electrode contact 538, and driven by one of four low-side drivers 540 in the quad low-side driver section of the chip 532.

The VCSEL array 534 has four columns 542 of emitters that each are connected to a common anode electrode contact 544, and driven by one of four high-side drivers 546 in the quad low-side driver section of the chip 532. The chip 532 also contains the electronic components in the shared diagnostics 548. For example, the shared diagnostics 548 can include all or part of the functions in the diagnostics module 310 and/or simple logic operations in the digital electronics 402 described in connection with FIGS. 3 and 4. This configuration can advantageously reduce size, cost and/or complexity of the sub-assembly 530.

FIG. 5C illustrates an embodiment of a transmit subassembly 560 for a VCSEL array 576 for a monitored LiDAR transmitter with separate diagnostics circuits 562, 564 for the low side and high side driver of the present teaching. Two separate chips 566, 568 are used to implement the diagnostics circuits 562, 564. One chip 568 includes four high-side driver circuits 570 that each are connected to a common anode contact 572 that connects a column 574 of emitters in the VCSEL array 576. The second chip 566 includes four low-side driver circuits 578 that are each connected to a common cathode contact 580 that connects a row 582 of emitters in the VCSEL array 576. Each chip 566, 568 also contains the electronic components in the separate diagnostics 564, 562 for the respective high- or low-side driver side. Each of the separate diagnostics 564, 562 can include all or part of the functions in the diagnostics module 310 and/or simple logic operations in the digital electronics 402 described in connection with FIGS. 3 and 4. This configuration can advantageously reduce size, cost and/or complexity and also improve the layout alignment of the transmit subassembly 560.

Referring to FIGS. 5B-5C, as an example, a comparator in the diagnostics circuit associated with the high side, either shared circuit 548 or separate diagnostic circuit 562 compares each output voltage provided by a high-side driver 546, 570 to a predetermined value high threshold voltage, referred to as TH_HIGH. The comparator outputs can be latched into a register after a predetermined delay time from enabling the high-speed driver 546, 570. The latched result is bit XOR-ed with an address bit and masked with an optional mask bit in the shared diagnostics circuit 548 or separate diagnostic circuit 562. The result can be stored in an error sticky bit in the shared diagnostics circuit 548 or separate diagnostic circuit 562 until it is read out by an upstream controller (not shown in FIGS. 5B-C).

In operation, an error bit is high, that is, representing an error condition, for two example cases that are described in detail below. The first example is if the high-side emitter at an address (also referred to as a channel) is higher than TH_HIGH, this indicates the channel is active while a different channel was selected (or stuck at high channel), and so represents an error in channel selection. The second example is if the high-side channel is lower than TH_HIGH and this channel was selected, it indicates a bad high-side channel. This could mean, for example, a short circuit or a short with an adjacent channel.

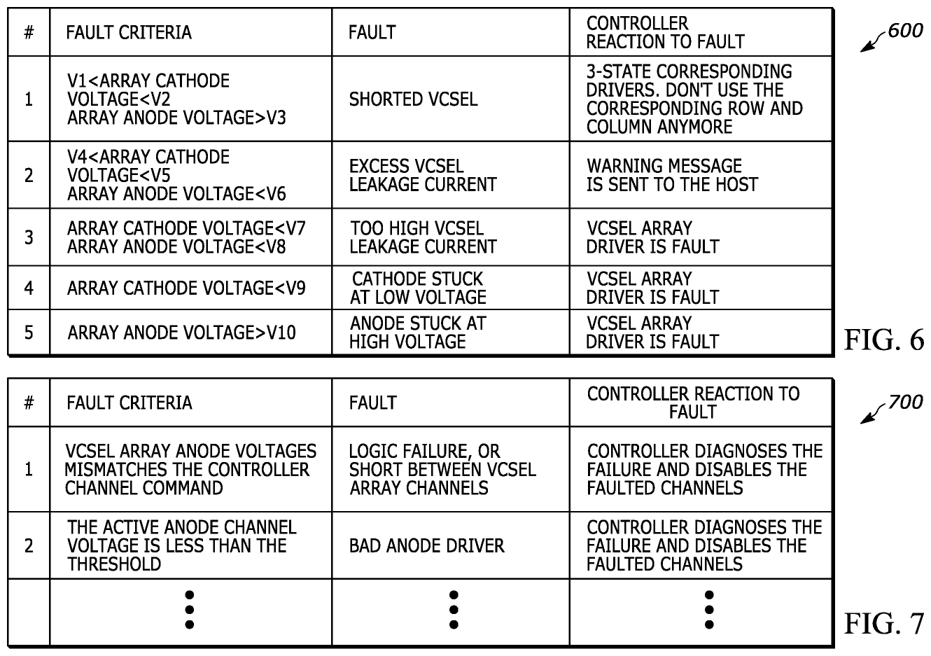

FIG. 6 illustrates a table 600 showing example embodiments of fault criteria, faults, and controller reactions for idle operation for a monitored LiDAR system of the present teaching. Example faults that can be identified include various shorts of VCSEL anode and/or cathode contacts, excess leakage current in a VCSEL, excess leakage current beyond a threshold level in a VCSEL, and cathodes and/or anodes stuck at a high voltage. Various threshold voltages (V1, V2, V3, V4, V5, V6, V7, V8, V9 and V10) are indicated as part of various fault criteria that can be used to identify the corresponding faults. This representation serves to indicate that these voltages can be selected independently, and not necessarily that they are different values. For example, as described herein, those voltages indicating a lower value of an array cathode and/or anode voltage may all share a common value of a low voltage threshold. For example, different sections of the arrays may have different values, or the same values, of threshold voltages for the low-end of ranges, as desired. This may be, for example, TH_LOW in the examples herein. For example, as described herein, those voltages indicating a higher value in a range of an array cathode and/or anode voltage may all share a common value of a high voltage threshold. This may be, for example, TH_HIGH in the examples herein. In addition, the TH_HIGH and TH_LOW thresholds can be applied to anodes and/or cathodes as described. In some embodiments, a TH_HIGH for an anode will have a different value than a TH-HIGH for a cathode and TH_LOW for an anode will have a different value than a TH-LOW for a cathode.

Various actions can be taken in response to the identification of a fault. Referring to FIG. 2A, the actions can be taken by any or all of the transmit electronics and laser driver 204, the controller 202 and/or the host processor 214, as appropriate. Example actions include displaying warning messages, performing shut downs of all or part of the laser emitters and/or associated drivers, making changes in firing patterns of the emitters, re-purposing parts of the array and its control scheme, and implementing other actions including, and in addition to, those listed in the table 600.

One feature of the present teaching is that the monitored transmitter can identify faults associated with the anode, high-side driven, electrode side (or sides) of the VCSEL array. FIG. 7 illustrates a table 700 showing example embodiments of fault criteria, faults and controller reactions for active operation at high-side drive for a monitored LiDAR system of the present teaching. Referring to FIGS. 3 and 4, a logic failure or a short between VCSELs can be indicated if the anode drive voltages generated by the high-side drivers 304 do not match the command desired drive voltages generated by the digital logic 312, as determined by the digital electronics 402. These two types of failures can be distinguished, for example, by comparing adjacent array elements (and/or driver addresses). The digital electronics 402 can identify the fault. The digital electronics 402 and/or the digital logic 312 can then take action to disable the faulted channels if a short is discovered. The digital electronics 402 and/or the digital logic 312 can also take appropriate action to remedy the logic failure or addressing failure if that is the determined reason for the voltage mismatch.

In addition, the monitored transmitter of the present teaching can find faults in the drivers. For example, a bad anode high-side driver can be determined if an active anode channel voltage is lower than a TH_HIGH threshold level for an anode. In this case, the output of the high-side driver 304 as measured by the diagnostics 310, is producing a voltage that is less than the desired voltage.

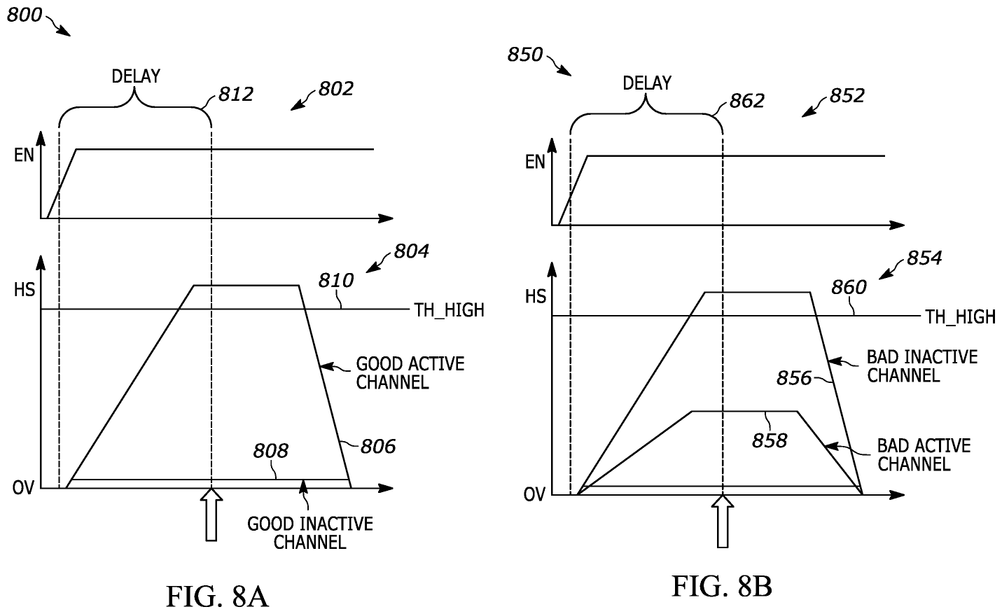

FIG. 8A illustrates graphs 800 that show the time dependence of good active and inactive channels and high threshold at anodes for a monitored LiDAR system of the present teaching. The top graph 802 illustrates the timing of a control pulse to energize a particular emitter at a particular address. The lower graph 804 shows example high side voltages as a function of time generated by the laser driver in response to the control pulse. A voltage pulse for a good active channel 806, which is for the channel addressed by the controller, is shown. In addition, a voltage pulse for a good inactive channel 808, that is for a channel not addressed by the controller, is also shown. A TH_HIGH threshold voltage is also shown 810. Referring to FIGS. 3 and 4, the comparators 412 compare the anode voltages (good active channel 806) to the predetermined value, TH_HIGH, after a delay 812. The delay 812 is chosen such that the sampled voltage of the active channel 806 is after any expected ramp up time. The value of the voltage of the good active channel 806 is not below TH_HIGH. The result is that the output of the comparator 412 is not latched into a fault register after the predetermined delay time, because the good active channel voltage 806 exceeds the TH_HIGH.

In general, the monitoring system captures the state of the anode drive voltage during a firing or energizing of a laser and compares it to a desired state at a time during the firing. This process captures fault conditions in the various components such as the laser array, electrodes and other electrical connections, driver circuit and/or digital logic that controls the drivers. The monitoring system does not need to react to conditions that represent good operations.

FIG. 8B illustrates graphs 850 that show the time dependence of bad active and inactive channels and high threshold at anodes for a monitored LiDAR system of the present teaching. The top graph 852 illustrates the timing of a control pulse to energize a particular emitter positioned in the array as represented by a particular address. The lower graph 854 shows example high side voltages as a function of time generated by the laser driver in response to the control pulse. A voltage pulse for a bad inactive channel 856 that is for a channel not addressed by the controller is shown in the graph. A voltage pulse for a bad active channel 858 is also shown in the graph. By active channel we mean the channel addressed by the controller.

A TH_HIGH threshold voltage is also shown as 860. Referring also to FIGS. 3 and 4, the comparators 412 compare the anode voltages (e.g. bad inactive channel 856) to the predetermined value, TH_HIGH, after a delay 862. The delay 862 is chosen such that the sampled voltage of the inactive channel 856 is after any expected ramp up time. The voltage of the bad inactive channel 856 falls above the TH_HIGH. The output of the comparator 412 is latched into a fault register after the predetermined delay time detecting the fault. This could be, for example, and addressing error where the actual drive voltage for a VCSEL at an address is driven high, even though the controller was asking for the VCSEL at that address to be low, or inactive.

We note that the bad active channel condition 858 is not identified by a comparison of TH_HIGH voltage. For this kind of fault, a TH_LOW threshold is implemented. In general, the monitoring system captures the state of the anode drive voltage during a firing or energizing of a laser and compares it to a desired state at a time during the firing. This can include providing both a TH_HIGH and a TH_LOW for each driver. Referring also as an example to FIG. 4, when the comparison yields an excursion beyond the set threshold, the output of the comparator 412 is latched into a fault register after the predetermined delay time if the comparator determines a fault. In general, in many embodiments, the monitoring system captures the state of the actual drive voltage during a firing or energizing of a laser and compares it to a desired drive voltage for a particular laser address at a time, which can be a delay after the issuing of the energize control signal, and occurs during the firing. Inactive (non-addressed) channels may also be monitored in this way. This process can efficiently and effectively capture fault conditions in the laser array, electrodes, and other electrical connections, driver circuit and/or digital logic that controls the drivers.

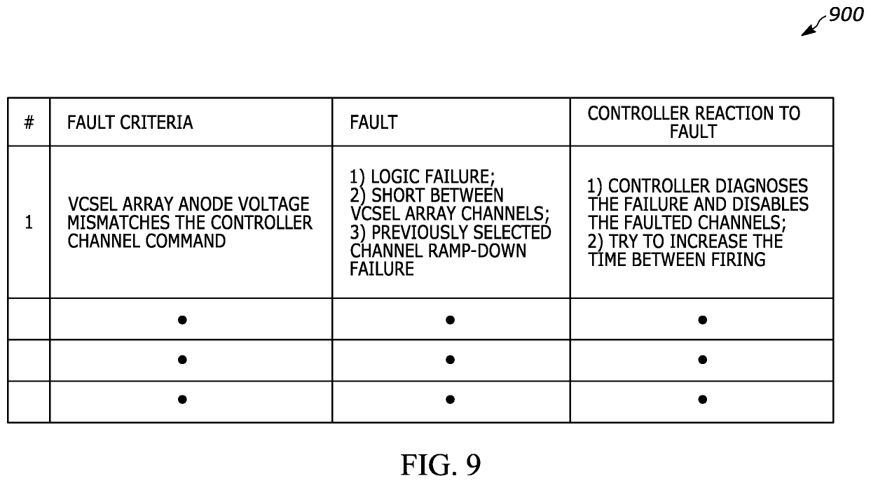

As described herein, the high-side drive, which is connected to anode contacts, can make use of both a high-threshold voltage and a low threshold voltage. FIG. 9 illustrates a table 900 showing example embodiments of fault criteria, faults, and controller reactions for low-voltage threshold at anodes for a monitored LiDAR system of the present teaching. The VCSEL array anode drive voltage being above a low-voltage threshold can indicate a logic failure or addressing failure, a short between array channels, or a ramp-down error from a previously energized array element. The controller or system can react by disabling the faulted channel. In addition, increasing a period of the firing time can also be implemented, for example, if the previous channels are found to be ramping down during a subsequent activation cycle. In this case, lengthening time between firings can avoid the problem.

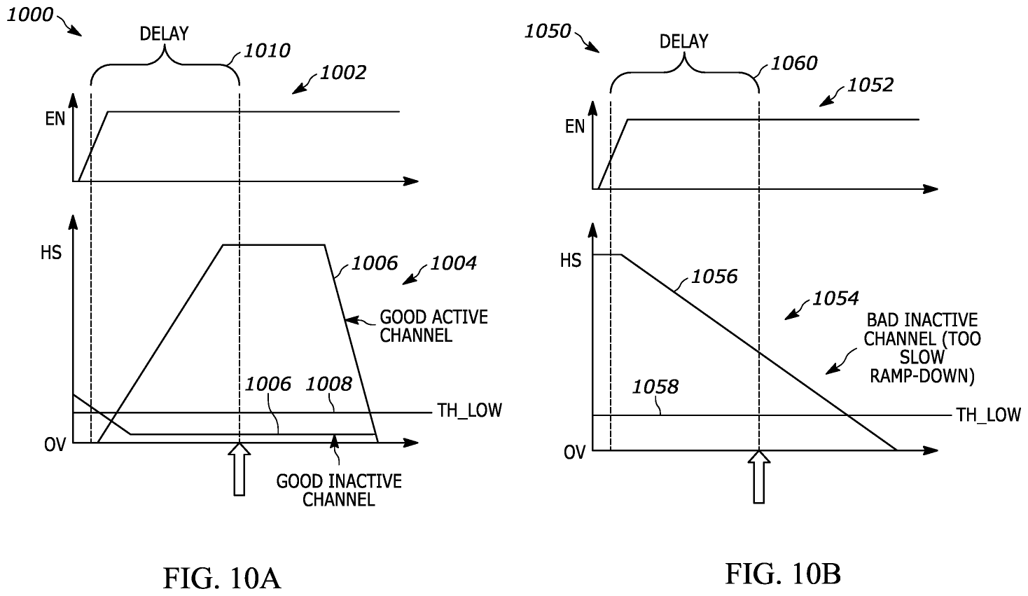

FIG. 10A illustrates graphs 1000 that show the time dependence of good active and inactive channels and threshold at a low-voltage threshold at anodes for a monitored LiDAR system of the present teaching. The top graph 1002 illustrates the timing of a control pulse to energize a particular emitter positioned in the array as represented by a particular address. The lower graph 1004 shows example high-side voltages as a function of time generated by the laser driver in response to a control pulse. A voltage pulse as a function of time for a good active channel 1006 is shown. By good active channel, we mean a channel addressed by the controller. A voltage pulse that would be considered good for an inactive channel 1008, is also shown along with the TH_LOW threshold voltage 1008. It is important that an inactive channel stay below the TH-LOW voltage 1008 as measured at a chosen delay 1010 after the initiation of the energizing control information shown in the top graph 1002.

FIG. 10B illustrates graphs that show the time dependence of a bad inactive channel and threshold at a low-voltage threshold at anodes for a monitored LiDAR system of the present teaching. The top graph 1052 illustrates the timing of a control pulse to energize a particular emitter positioned in the array as represented by a particular address. The lower graph 1054 shows example high-side voltages as a function of time generated by the laser driver in response to a control pulse. A voltage pulse as a function of time 1056 for a bad inactive channel that has too slow of a ramp down is shown as is the TH_LOW threshold value that it is compared at a delay 1060 after control pulse onset. The voltage pulse as a function of time 1056 for a bad inactive channel will exceed the TH_LOW value.

In some embodiments, a comparator compares each output voltage for a given channel to the predetermined value (TH_LOW) 1058. The output of the comparator latches into a register after a predetermined delay time from enabling the control pulse. In this case, that would be for channels that are supposed to be inactive, but exhibit voltage in excess of the TH_LOW. The latched result can be bit XOR-ed with the address bit, masked with an optional mask bit, and the result stored in an error sticky bit. The error bit is high, indicating a fault, in at least two cases. First, if the anode high-side driven channel output is higher than TH_LOW and the channel is supposed to be inactive (that is, a different channel was selected), this condition could mean either a slow ramp-down of the previously selected HS channel or an error in channel selection. If the anode high-side driven channel output is lower than TH_LOW although this channel was selected to be active, it indicates a bad channel that could be a short circuit or short with an adjacent channel.

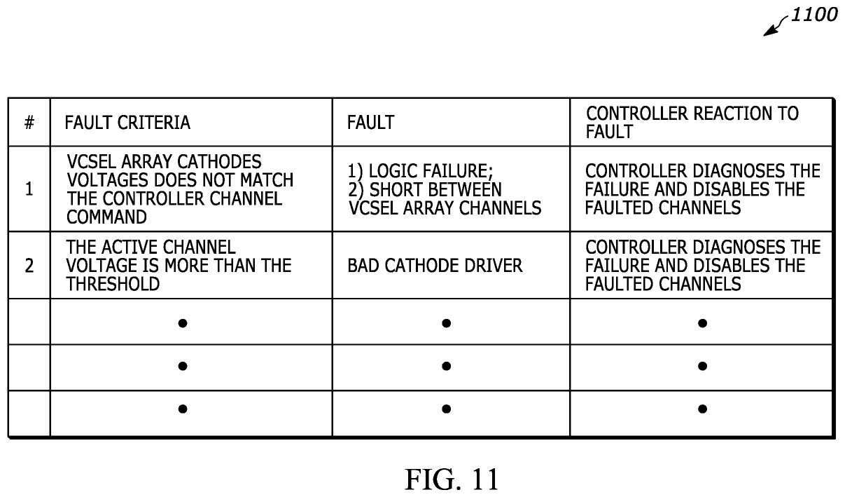

Another feature of the present teaching is that it can monitor at multiple points of the system including a LiDAR transmitter at the low-side, cathode electrode of the LiDAR transmitter and/or the high-side driven anode electrode. FIG. 11 illustrates a table 1100 showing example embodiments of fault criteria, faults and controller reactions for active channels at a low-voltage threshold at cathodes for a monitored LiDAR system of the present teaching. Fault criteria can include the cathode drive voltages that do not match the desired control voltages. This can indicate faults such as logic failure, and a short between VCSEL array channels. In these cases, the controller can diagnose the failure and/or disable the faulted channel. Another fault criterion is when the active channel at the cathode is presented with a drive voltage that is greater than a threshold voltage. This condition can be caused by a bad cathode driver, and can be remediated by disabling the faulted channel.

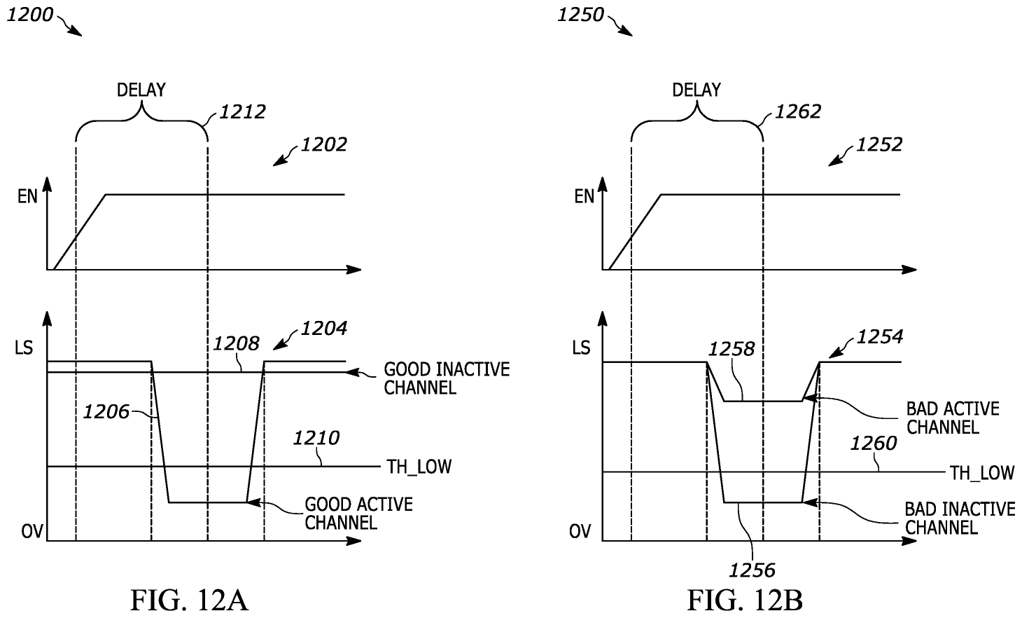

FIG. 12A illustrates graphs 1200 that show the time dependence of good active and inactive channels and threshold at a low-voltage threshold at cathodes for a monitored LiDAR system of the present teaching. The top graph 1202 illustrates the timing of a control pulse to energize a particular emitter at a particular address. The lower graph 1204 shows example low-side voltages as a function of time generated by the low-side laser driver in response to the control pulse. A voltage pulse for a good active channel 1206, which is for the channel addressed by the controller, is shown. A voltage pulse for a good inactive channel 1208, which is for a channel not addressed by the controller, is also shown. A TH_LOW threshold voltage is also shown 1210.

Referring back to FIGS. 3 and 4, the comparators 414 compare the cathode voltages by low side driver 308 (e.g. good active channel 1206) to a predetermined value, TH_LOW 1210, after a delay 1212. The TH_LOW and the conditions for a particular drive signal are related to the particular control signal provided by the digital logic 312. The delay 1212 is chosen such that the sampled voltage of the active channel 1206 is after any expected reaction time for a voltage level change. The value of the voltage of the good active channel 1206 is below TH_LOW. The good inactive channel trace 1208 is also above TH_LOW. The output of the comparator 414 is not latched into a fault register after the predetermined delay time because the good active channel voltage 1206 is less than TH_LOW. In general, the monitoring system captures the state of the cathode drive voltage during a firing or energizing of a laser and compares it to a desired state as indicated by the control pulse at a time during the firing. This process captures fault conditions in the laser array, electrodes and other electrical connections, the driver circuit and/or digital logic that controls the drivers. The process also can be configured to not react to non-fault conditions.

FIG. 12B illustrates graphs 1250 that show the time dependence of a bad active and inactive channels and threshold at a low-voltage threshold at cathodes for a monitored LiDAR system of the present teaching. The top graph 1252 illustrates the timing of a control pulse to energize a particular emitter positioned in the array as represented by a particular address. The lower graph 1254 shows an example for low-side voltages as a function of time generated by the laser driver in response to the control pulse. A voltage pulse for a bad inactive channel 1256, which is for a channel not addressed by the controller, is shown. A voltage pulse for a bad active channel 1258, which is a channel addressed by the controller, is also shown along with a TH_LOW threshold voltage 1260.

Referring to FIGS. 3 and 4, the comparators 414 compare the cathode voltages (e.g. bad inactive channel 1256) generated by a low-side driver 308 to the predetermined value, TH_LOW, after a delay 1262. The delay 1262 is chosen such that the sampled voltage of the inactive channel 1256 is after any expected reaction time to the firing control signal.

In a fault condition, the voltage of the bad inactive channel 1256 falls below the TH_LOW. The output of the comparator 414 is latched into a fault register after the predetermined delay time detecting the fault for the address of this inactive channel. The voltage of the bad active channel 1258 falls above the TH_LOW. The output of the comparator 414 is latched into a fault register after the predetermined delay time detecting the fault for the address of this active channel.

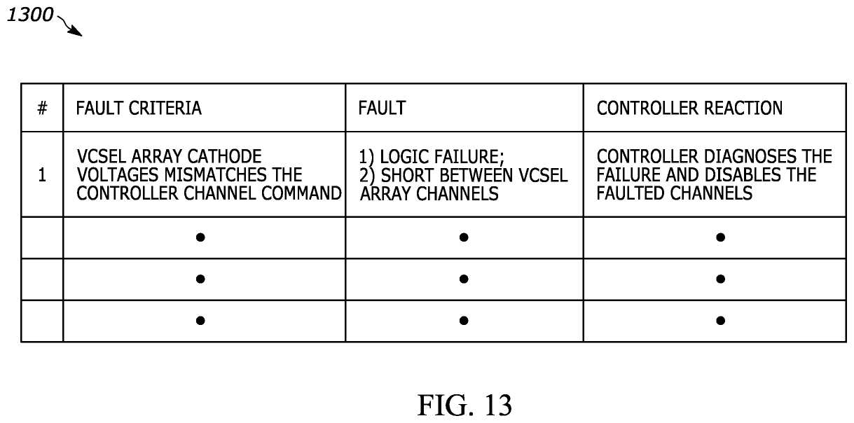

FIG. 13 illustrates a table 1300 showing example embodiments of fault criteria, faults and controller reactions for active channels at a high-voltage threshold for cathodes for a monitored LiDAR system of the present teaching. Comparing the cathode voltage to a high voltage threshold, TH_HIGH, can identify faults such as a logic failure, an addressing failure, and/or a short between VCSEL array channels. The controller can react by disabling faulted channels, or resetting addresses.

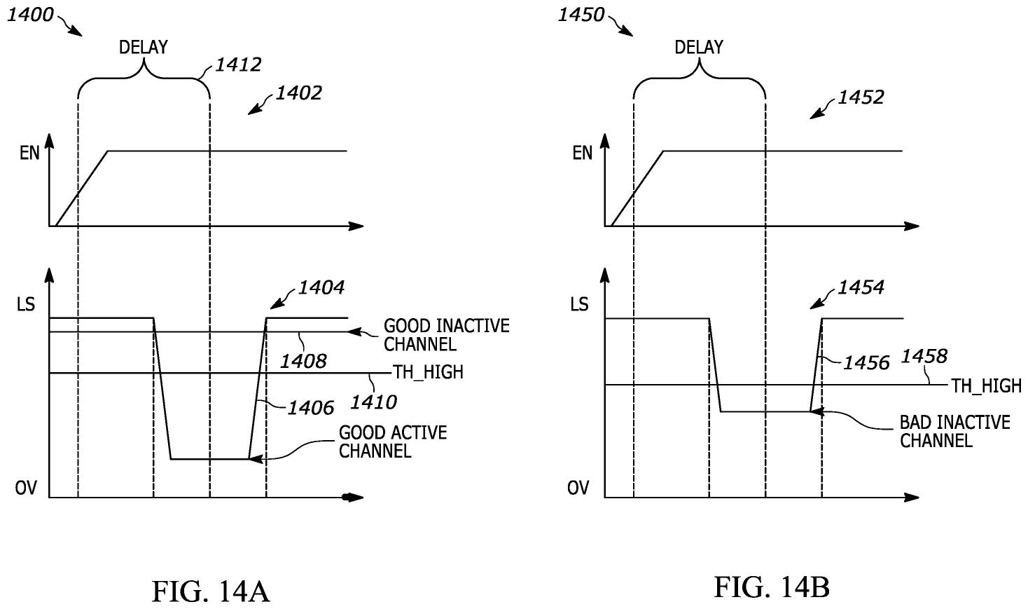

FIG. 14A illustrates graphs 1400 that show the time dependence of good active and inactive channels and threshold at a high-voltage threshold at cathodes for a monitored LiDAR system of the present teaching. The top graph 1402 illustrates the timing of a control pulse to energize a particular emitter at a particular address. The lower graph 1404 shows example low-side voltages as a function of time generated by the low-side laser driver in response to the control pulse. A voltage pulse for a good active channel 1406, which is for the channel addressed by the controller, is shown. A voltage pulse for a good inactive channel 1408, which is for a channel not addressed by the controller, is also shown. A TH_HIGH threshold voltage is also shown 1410.

Again referring to FIGS. 3 and 4, the comparators 414 compare the cathode voltages by low-side driver 308 (e.g., good active channel 1406) to a predetermined value, TH_HIGH 1210, after a delay 1412. The TH_HIGH and the conditions for a particular drive signal are related to the particular control signal provided by the digital logic 312. The delay 1412 is chosen such that the sampled voltage of the active channel 1406 is after any expected reaction time for a voltage level change. The value of the voltage of the good active channel 1406 is below TH_HIGH. The good inactive channel trace 1408 is above TH_HIGH. The result is that the output of the comparator 414 is not latched into a fault register after the predetermined delay time because the good active channel voltage 1406 is less than TH_HIGH and so is the good inactive channel.

FIG. 14B illustrates graphs 1450 that show the time dependence of a bad inactive channel and threshold at a high-voltage threshold at cathodes for a monitored LiDAR system of the present teaching. The top graph 1452 illustrates the timing of a control pulse to energize a particular emitter positioned in the array as represented by a particular address. The lower graph 1454 shows an example of low-side voltages as a function of time generated by the laser driver 308 in response to the control pulse. A voltage pulse for a bad inactive channel 1456, which is for a channel not addressed by the controller, is shown along with a TH_HIGH threshold voltage 1458.

Again referring to FIGS. 3 and 4, the comparators 414 compare the cathode voltages (e.g., bad inactive channel 1456) generated by a low-side driver 308 to the predetermined value, TH_HIGH, after a delay 1460. The delay 1460 is chosen such that the sampled voltage of the inactive channel 1456 is after any expected reaction time to the firing control signal. The voltage of the bad inactive channel 1456 falls below the TH_HIGH. The output of the comparator 414 is latched into a fault register after the predetermined delay time detecting the fault for the address of this inactive channel.

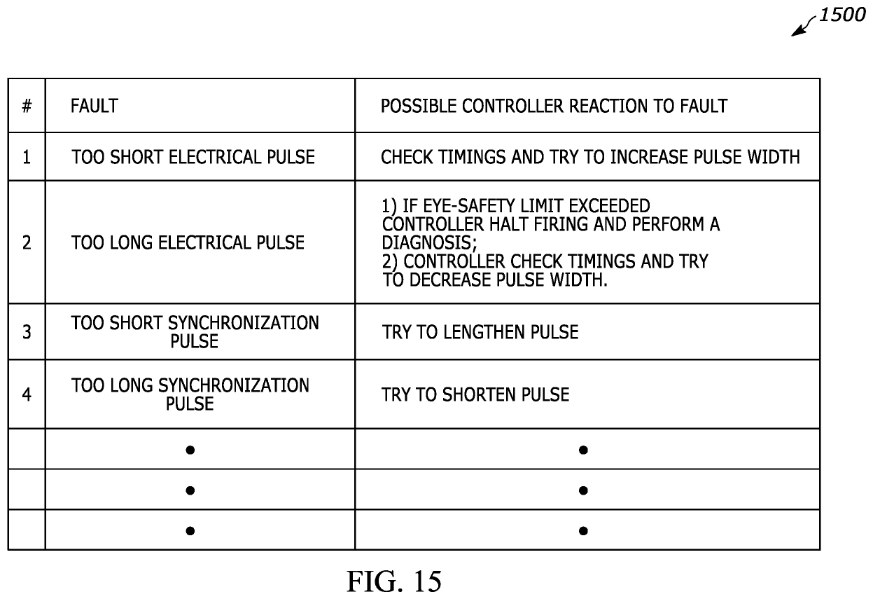

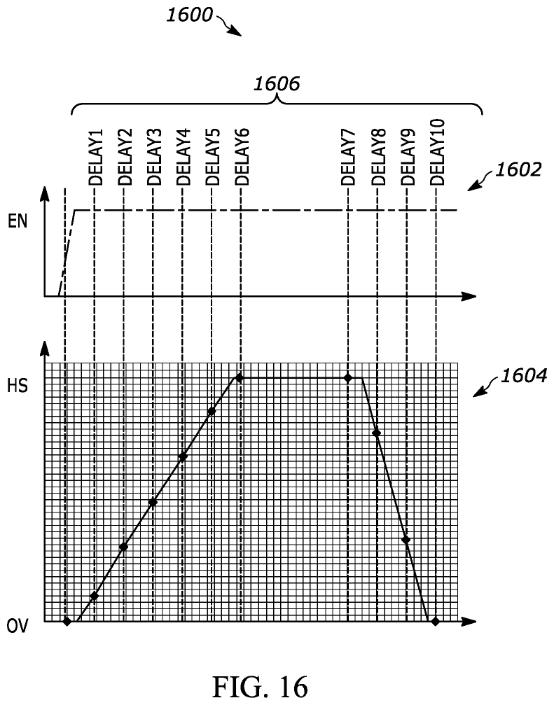

One feature of the present teaching is that it can provide fault monitoring based on timing errors in the LiDAR transmitter separately from, or in addition to, the voltage-threshold-based criteria. FIG. 15 illustrates a table 1500 showing example embodiments of faults and controller reactions relating to monitored pulse width for a monitored LiDAR system of the present teaching. Multiple TDCs (time-to-digital) can be used to monitor the system timings such as propagation delays, pulse widths (or duration) and pulse periods. These can all be compared to desired values. The following are some examples.

If a pulse duration of an active channel is determined to be too short, the pulse width can be increased. If a pulse duration of an active channel is determined to be too long, the system can further determine if an eye safety limit is exceeded, and in response can shut down the active element. If a pulse duration is too long, but also still safe, the reaction can be different. For example, the reaction can be shortening the pulse, but not shutting down the laser element to keep the system operating at high performance. In some embodiments, synchronization pulses are used, and these can also be checked using a TDC to determine if the pulse is too short or too long to an extent that triggers a fault condition so corrective action taken in these fault condition.

FIG. 16 illustrates graphs 1600 that show the time dependence of a pulse in a high-side drive at anodes for a monitored LiDAR system of the present teaching. The top graph 1602 illustrates the timing of a control pulse to energize a particular emitter at a particular address. The lower graph 1604 shows an example high-side voltage pulse as a function of time generated by the laser driver in response to the control pulse. A series of different delays 1606, DELAY1, DELAY2 . . . DELAY10, from the onset of the control pulse are used to probe the pulse at different times. Different high voltage thresholds, TH_HIGHX, where X=1, 2, 3, . . . 10, are used for different delays. This allows a more detailed extraction of the high-side or low-side electrical pulse shape. This more detailed time-based extraction of the voltages allows more sophisticated conditions to be established. For example, a successive approximation algorithm can be used to find the voltage level at a given delay. This can be used for several purposes. For example, the time-based thresholding can be used during the electrical turn-up of the printed circuit board assembly. Time-based thresholding can be used for system delay tuning. By extracting the high-side pulse shape, the system can determine which delay is required between the high-side and low-side controls. During the extensive system testing at power-up, each channel pulse shape can be diagnosed to find a fault channel. For example, faults can be based on too slow or too fast of a rise time and/or a fall time of a pulse voltage. It should be understood that FIG. 16 and the corresponding description which teaches the use of delays in connection with a high-side drive pulse case can be applied to the time-based thresholding and fault condition detection for a low-side drive pulse as well.

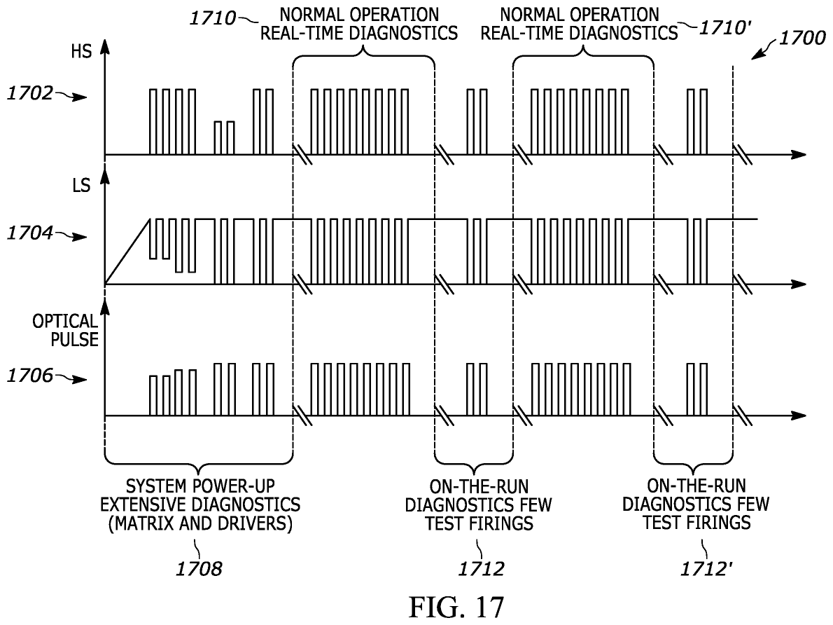

FIG. 17 illustrates a timing diagram 1700 for the high-side drive 1702 and low-side drive 1704 and optical pulses 1706 of an embodiment of the monitored LiDAR system of the present teaching. There are three main regions of operation illustrated in this embodiment. A system power up region 1708 can include extensive diagnostics of the VCSEL matrix, and individual elements as well as the drivers associated with all or some of the addresses. The power up region can be followed by normal operation regions 1710, 1710′. These normal operating regions 1710, 1710′ can be separated by on-the-run diagnostics regions 1712, 1712′. In the normal operation regions 1710, 1710′, real-time diagnostics are run on the live laser drive signals. A characteristic of this region 1710, 1710′ is that the system avoids firing of any laser that is not part of taking scene data. In the on-the-run diagnostics regions 1712, 1712′, unlike the normal operation regions 1710, 1710′, test firings of lasers are allowed.

Example operation of the monitored LiDAR transmitter of the present teaching can be described in the following way. The laser transmit logic/controller (e.g., digital logic 312 of FIG. 3 or controller interface 202 of FIG. 2 or both) counts the number of firings (i.e., laser drive pulses applied). The host (e.g., host 214 of FIG. 2) compares this number to the actual number of firings (i.e., laser pulses emitted). The laser transmit logic/controller calculates the firing energy (number of pulses at a given time) and stops firing if the eye-safety limit is exceeded.

The pulse duty-cycle is diagnosed using an energy related mechanism as determined by the TDC. For example, a moving average can be calculated by counting the number of pulses each predetermined window. When the count exceeds a predetermined threshold, an error flag is raised. In some embodiments, digital-oriented calculation methods like a “leaky bucket” can be used. The use of a TDC allows the determination of actual current pulse width, propagation delay diagnostics, and adaptation. In these embodiments, a TDC is connected to a digital comparator that generates fail-high and fail-low errors. The use of a TDC enables calibration of each individual VCSEL propagation delay, which can improve calibration of the system. In addition, by using a TDC, the actual pulse count can be diagnosed to enable a comparison to the expected pulse count.

Another feature of the apparatus and methods of the present teaching is that it allows LiDAR performance to be adapted to particular desired operational performance as well as reliability. The Society of Automotive Engineers (SAE) defines six levels of driving automation ranging from 0, or fully manual, to 5, or fully autonomous. For levels 0-2, the human driver monitors the driving environment. For levels 3-6, an automated system monitors the driving environment with varying levels of accuracy and functionality.

Monitoring is performed though a combination of different sensors and technologies such as radar, cameras, and sonar for detection and location of surrounding objects. Among these sensor technologies, light detection and ranging (LiDAR) systems take a critical role, enabling real-time, high resolution 3D mapping of the surrounding environment.

Sensors intended for use in autonomous driving typically need to comply with international safety standards, such as the Industry Organization for Standardization (ISO) 26262 standard entitled “Road vehicles—Functional safety” defined initially in 2011 and revised in 2018. Functional safety is part of the overall safety of a system or piece of equipment that depends on automatic protection. The automatic protection system is designed to respond to various types of system failures to prevent possible hazards or reduce their severity. System failures could be due to human errors, hardware failures, and operational/environmental stress.

The ISO 26262 standard addresses possible hazards caused by the malfunctioning of electronic and electrical systems in passenger vehicles, as determined by the Automotive Safety Integrity Level (“ASIL”). ASIL addresses four different risk levels (A, B, C, and D) determined by three factors: (1) Exposure (the probability of the hazard), (2) Controllability (can the driver respond to the hazard), and (3) Severity (the types of injuries). The ASIL risk level is roughly defined as the combination of Severity, Exposure, and Controllability.

A LiDAR sensor must also comply with international standards for eye safety because it incorporates at least one laser. Regulations have been established to set standards for the allowable amount of laser radiation to ensure that products are labeled in such a fashion that consumers understand the safety risks associated with a particular product. The most referenced standard worldwide is the IEC 60825-1 standard, published by the International Electrotechnical Commission (IEC), which has been adopted in Europe as the EN 60825-1 standard. In the US, laser products are covered by the CDRH 21 CFR 1040.10 standard, and compliance with the 60825-1 standard has been established as acceptable to meet the US federal standard.

In these eye safety standards, lasers are classified by wavelength and maximum output power into different safety categories. The standards define the maximum permissible exposure (MPE), which is specified as the optical power or energy that can pass through a fully open pupil, without causing any damage.

In systems where the laser is not operated continuously but is instead pulsed, the MPE is a function of energy, which is related to the laser pulse duration and the duty cycle. A Class 1 laser is safe under all conditions of normal use. The maximum permissible exposure (MPE) cannot be exceeded in a Class 1 product. It is therefore highly desirable for an automotive LiDAR system to be Class 1 eye safe.

Ensuring a LiDAR system complies with international safety standards requires a rigorous development process and robust design. Special attention should be paid to detection of the occurrence of faults and out-of-control behavior within the electronic, optical, and electrical systems, which can happen during the lifetime of the system. The monitored LiDAR system of the present teaching enables this detection, and subsequent reaction to faults and out-of-control behavior.

In a LiDAR system for autonomous cars, Class 1 eye safety should be maintained, while also maximizing the measurement range. Range is a function of signal-to-noise and, therefore, will increase correspondingly with maximizing the peak optical power of the transmit laser. However, Class 1 eye safety restricts the maximum peak optical power together with the pulse duration/frequency.

For example, we can calculate from the IEC 60825-1 standard that for an exposure duration between 10 psec and 5 μsec, the allowable exposure energy for a 903 nm laser, will be 0.392 μJoules. So, if a single laser pulse of duration 5 nsec was transmitted every 5 μsec, and the pulse was assumed to be square in shape (zero rise/fall time), the maximum peak power of this pulse would be 78.4 W. Correspondingly, if the square pulse were 50 nsec in duration, the maximum peak power would be 10× less, or 7.84 W.

Lasers which can achieve these peak powers can typically be used to produce higher optical powers as well if appropriate bias current is supplied. It is important to include monitoring of optical transmit power in these LiDAR systems in order to know more definitively that the optical pulse energy (integrated power over time) is not exceeding the MPE for Class 1 eye safety. For example, a monitor photodiode 227 as described in connection with FIG. 2B can be used. See, for example, U.S. patent application Ser. No. 15/915,840, entitled Eye-Safe Scanning LIDAR System and U.S. Provisional Patent Application No. 63/112,735 entitled LiDAR System with Transmit Optical Power Monitor, which are both assigned to the present assignee and are incorporated herein by reference.

Optical monitoring by itself provides critical feedback for eye safety, but additional fault monitoring as described herein is needed in order to localize the exact fault condition and to determine additional details that can be used to inform the host of the fault condition and/or to potentially adapt the system operating parameters to compensate or correct the fault. With a multi-laser LIDAR system, there could be shorts or electrical cross-talk that result in a laser being unintentionally fired. If more than one laser is being fired simultaneously or close enough in time to another laser, then it is necessary to consider their combined energy with regard to addressing the eye safety limit considerations. It also can be important to confirm that a laser is not being fired unintentionally through some unintended cross-talk, or electrical short in the electronic circuit.

Many LiDAR systems construct 3D point cloud that accurately represent the environment in order to be able to detect and identify objects in the environment. If the 3D data is not accurate or reliable, then various types of hazards could occur. For instance, if an object is not detected in the path of the autonomous vehicle, and the vehicle is in motion, then a collision could occur resulting in monitory damages and possibly physical harm to individuals. LiDAR sensors have a measurement range limitation, so it is understood that for distant and/or low reflectance objects that at some distance the probability of detection drops to zero. A missing object, however, could also be the result of a fault condition with the LiDAR system. For example, a LiDAR system might experience a “blind spot” during operation which could be caused by several factors including a laser not firing correctly, dirt or other foreign material covering the lenses, and/or various types of errors in the receiver circuit. False negatives can occur from a bad active channel if a return signal is not received from a location because of various reasons including the laser not firing when expected.

Another potential problem with LiDAR systems is a so-called “false positive”, which means the LiDAR system reports the presence of an object that is not actually there in fact. This can also cause a functional safety hazard. For example, in the situation where an object is reported in the path of a moving vehicle, the auto-braking system might be triggered in order to avoid a potential collision. Unnecessary auto-braking can result in injuries to people and the vehicle, particularly when the vehicle is traveling at a high-rate of speed. False positives can occur, for example, from a bad inactive channel condition if laser light is reflected from a location that is not being actively probed and the received signal cannot be spatially distinguished by the detector array.

Another aspect related to safety is the usability of the LiDAR system once a fault has occurred during operation. It is highly undesirable for fault conditions in the LiDAR system to trigger a complete shutdown of the LiDAR system as shutting down the LiDAR system will result in a need for service to repair or replace components with the associated cost and inconvenience to the user, especially considering that it is unlikely that any part of the LiDAR system will be user serviceable. A shut down of the LiDAR system can also result in an unsafe conditions and even complete loss of use of the vehicle. In a fully autonomous vehicle, a shutdown of the LiDAR system will likely disable the vehicle. In any event, any trip in process would be adversely impacted by the LiDAR system shutting down.

Instead, it is desirable that the LiDAR system adjust to the fault condition in some fashion that allows the vehicle to continue to function, allowing completion of any trip in process at the time. Thus, the ability to isolate the location and/or the type of fault by the system and the method of the present teaching is important to practical commercialization of LiDAR systems.

Another feature of the present teaching is that multiple system-level responses to fault conditions identified by a monitored LiDAR transmitter can be implemented. For example, at the most basic level, the monitored LiDAR transmitter can inform a host of a fault condition. This is a basic action that the LiDAR system can take, and allows the host system to take an action based on the fault information. Decisions can also be taken at the LiDAR transmitter level such that the transmitter system continues to function in some fashion even after a fault has occurred. If eye safety is not being violated, for instance, then the LiDAR transmitter might continue to function under the fault condition, while communicating the fault condition to the host allowing the host to take some additional action (e.g., shut the sensor down, not use the data, or flag data as suspect, etc.) based on predetermined criteria or some kind of computer based algorithm. It should be understood that numerous types of artificial intelligence algorithms can be used by the host to determine what action to take for a particular fault condition.

One example of an algorithm that can be used by the system to improve performance is an algorithm that can communicate to the host the degree of severity of a fault condition. In this scenario, depending on the severity of the fault condition, the monitored LiDAR system might also make a recommendation about what action the host should take. A logic tree in the controller (e.g. controller 202 of FIG. 2) that is based on the fault condition can be used to supply additional information to the host. That is, not just a failure code is transmitted to the host, but also information relating to the health of the transmitter and/or particular lasers, such as the actual output power, the exact points in the FOV affected, and potentially a recommended action for the host to take. We note that various aspects of the algorithms that improve performance described herein can be implemented in different circuits and/or controllers in different embodiments of the LiDAR system described herein as appropriate to the particular function as understood by those skilled in the art.

Another example of an algorithm that can be used by the system to improve performance is an algorithm to perform self-diagnostic functions to better assess the fault condition and/or health of the transmitter, including individual VCELs. Also, several diagnostics tools can assess transmitter and/or the VCSEL health without generating an optical pulse. This means the transmitter and/or VCSEL could be checked before firing to make sure no potential damage, hazard, explosion, and/or fire will arise at a faulted transmitter and or VCSEL.

As an example of an algorithm that can be used by the system to improve performance is an algorithm to perform self-diagnostic functions to better assess the fault condition. When a fault condition occurs, the LiDAR system initiates some type of active self-diagnostic. For example, if a fault condition is detected where two lasers are firing simultaneously instead of one, a scan of the receiver could be run to investigate which detectors in the receiver are detecting a return signal for the two lasers. A monitor photodiode can also be used as part of a diagnostic test. In addition, algorithms can be used to change the bias level of the laser to determine if the laser's behavior changes in some expected way and then act on the resulting test data. Furthermore, algorithms can be used to fire adjacent lasers, or groups of lasers, and the actual behavior compared to some expected behavior, giving information about the laser giving the fault condition then to act on that test data to further diagnose the fault within the transmitter.

Another example of an algorithm that can be used by the system to improve system performance is an algorithm to adopt operating parameters according to particular fault conditions. For example, the system can alter laser firing sequences to adapt to a fault condition. As one particular example of this, in the event that the fault condition is a single laser in the FOV, the system can alter the laser firing map to not fire the bad laser any longer, and also to not waste the time slot allocated for firing the bad laser. Instead, the time slot allocated for firing the bad laser can then be used to fire adjacent lasers in the FOV to enhance the SNR for the area around the “blind spot” caused by the “bad laser”.

Yet another example of an algorithm that can be used to improve the performance of the system is an algorithm that alters the mapping of laser, or group of lasers, to a receive detector to adapt to fault conditions. If a laser significantly degrades or fails, the laser-to-detector mapping can be changed to eliminate the use of that particular laser for all detectors with which it is associated. Any detector that was using that laser would be reassigned to an adjacent laser based on control logic and the geometry of the array and electrical connection pattern. Also, it is known that at different distances the optimum mapping choice can change because of parallax. So, such a change can lead to some reduced optical coupling for at least some part of the detector array FOV that corresponds to a particular laser, but still retain functionality at some ranges. Yet another aspect of the present teaching is the understanding that using reassignment, the blind spot caused by one or more failed lasers can be made smaller with the temporary mapping. Such an approach may work better at shorter ranges, as the blind spot will be larger at longer ranges.

One feature of the system and method for active fault monitoring of the present teaching is that it can detect a fault condition and/or perform diagnostics for health conditions in a light detection and ranging (LiDAR) transmitter and the detected conditions can be reported to other systems in the vehicle and/or operational control system or host system within the LiDAR. For example, embodiments of the method can report an address and the fault condition to a host that takes an action on the LiDAR transmitter in response to the fault condition. The severity of an error can be reported. The health of individual VCSELs groups of VCSELs and/or the transmitter can be reported. For example, I the system detects that a particular laser appears to be degrading in performance, but not yet failing, the health of this laser could be reported to the host as an early warning, so that subsequent maintenance or further diagnostics could be performed in advance of further degradation. This reporting function can be useful as part of a functional safety system, because it allows the health and/or faults of the LiDAR transmitter to be included as part of the larger system that impacts the safety of the vehicle. For example, some embodiments of the method of the present teaching can support automotive safety lifecycle, including management, development, production, operation, service and decommissioning via, for example, the reporting step and/or automatic response to self-diagnostics. Some embodiments of the method of the present teaching can support determination of risk classes and/or specification of requirements associated with achieving an acceptable risk level via, for example, the reporting step and/or automatic response to self-diagnostics.

### EQUIVALENTS

While the Applicant's teaching is described in conjunction with various embodiments, it is not intended that the Applicant's teaching be limited to such embodiments. On the contrary, the Applicant's teaching encompasses various alternatives, modifications, and equivalents, as will be appreciated by those of skill in the art, which may be made therein without departing from the spirit and scope of the teaching.

What is claimed is:

1. A method for detecting a fault condition in a light detection and ranging (LiDAR) transmitter, the method comprising:
a) generating a control signal that comprises an address and desired drive voltage and current information for a laser in a laser array;
b) generating a drive signal for the laser in the laser array in response to the generated control signal and applying the generated drive signal to a contact associated with that address of the laser array, thereby energizing the laser at a desired output power for a desired time;
c) determining if the drive signal has a parameter with a value that is outside a threshold range for eye safety;
d) storing the address and a fault condition if the parameter has the value outside the threshold range for eye safety; and
e) reporting the address and the fault condition to a host that takes an action on the LiDAR transmitter in response to the fault condition.

2. The method of claim 1 wherein the laser comprises a group of lasers in the laser array.

3. The method of claim 1 wherein the parameter comprises drive signal pulse duration.

4. The method of claim 1 wherein the parameter comprises drive signal power.

5. The method of claim 1 wherein the parameter comprises drive signal repetition rate.

6. The method of claim 1 wherein the drive signal comprises a low-side drive signal.

7. The method of claim 1 wherein the drive signal comprises a high-side drive signal.

8. The method of claim 1 wherein the determining if the drive signal has a parameter with a value that is outside a threshold range for eye safety comprises performing an XOR operation.

9. The method of claim 1 wherein the determining if the drive signal has a parameter with a value that is outside a threshold range for eye safety comprises comparing the drive current to a predetermined low current value.

10. The method of claim 1 wherein the determining if the drive signal has a parameter with a value that is outside a threshold range for eye safety comprises comparing the drive voltage to a predetermined low voltage value.

11. The method of claim 1 wherein the determining if the drive signal has a parameter with a value that is outside a threshold range for eye safety comprises comparing the drive voltage to a predetermined high voltage value.

12. The method of claim 1 wherein the determining if the drive signal has a parameter with a value that is outside a threshold range for eye safety comprises comparing the drive current to a predetermined high current value.

13. The method of claim 1 wherein the determining if the drive signal has a parameter with a value that is outside a threshold range for eye safety comprises comparing the drive current to a predetermined low current value.

14. The method of claim 1 wherein the determining if the drive signal has a parameter with a value that is outside a threshold range for eye safety comprises comparing the drive voltage to a predetermined low voltage value.

15. The method of claim 1 wherein the determining if the drive signal has a parameter with a value that is outside a threshold range for eye safety comprises comparing the drive voltage to a predetermined high voltage value.

16. The method of claim 1 wherein the determining if the drive signal has a parameter with a value that is outside a threshold range for eye safety comprises comparing the drive current to a predetermined high current value.

17. The method of claim 1 wherein the drive voltage is a high side drive voltage.

18. The method of claim 1 wherein the drive voltage is a low side drive voltage.

19. The method of claim 1 wherein the laser array comprises a two-dimensional laser array.

20. The method of claim 19 wherein the laser array has at least two lasers that can be operated independently.

21. The method of claim 1 further comprising reporting a severity of the fault condition to the host.

22. The method of claim 1 further comprising performing additional diagnostics in response to the fault condition.

23. The method of claim 1 wherein the host adapts operating parameters based on the fault condition.

24. The method of claim 1 wherein the host alters the firing sequence based on the fault condition.

25. The method of claim 1 wherein the host alters the laser-to-pixel mapping based on the fault condition.

26. The method of claim 1 further comprising reporting health status to a host that takes an action on the LiDAR transmitter in response to the health status.

27. A method for detecting a fault condition in a light detection and ranging (LiDAR) transmitter, the method comprising:
a) generating a control signal that comprises an address and desired drive voltage information for a laser in a laser array;
b) generating a drive signal for the laser in the laser array in response to the generated control signal and applying the generated drive signal to a contact associated with that address of the laser array, thereby energizing the laser at a desired output power for a desired time;
c) determining if the drive signal has a parameter with a value that is outside a threshold range for functional safety;
d) storing the address and a fault condition if the parameter has the value outside the threshold range for functional safety; and
e) reporting the address and the fault condition to a host that takes an action on the LiDAR transmitter in response to the fault condition.

28. The method of claim 27 wherein the determining if the drive signal has a parameter with a value that is outside a threshold range for functional safety comprises comparing the drive current to a predetermined low current value.

29. The method of claim 27 wherein the determining if the drive signal has a parameter with a value that is outside a threshold range for functional safety comprises comparing the drive voltage to a predetermined low voltage value.

30. The method of claim 27 wherein the determining if the drive signal has a parameter with a value that is outside a threshold range for functional safety comprises comparing the drive voltage to a predetermined high voltage value.

31. The method of claim 27 wherein the determining if the drive signal has a parameter with a value that is outside a threshold range for functional safety comprises comparing the drive current to a predetermined high current value.

32. The method of claim 27 wherein the drive voltage is a high side drive voltage.

33. The method of claim 27 wherein the drive voltage is a low side drive voltage.

34. The method of claim 27 wherein the laser array comprises a two-dimensional laser array.

35. The method of claim 34 wherein the laser array has at least two lasers that can be operated independently.

36. The method of claim 27 further comprising reporting a severity of the fault condition to the host.

37. The method of claim 27 further comprising performing additional diagnostics in response to the fault condition.

38. The method of claim 27 wherein the host adapts operating parameters based on the fault condition.

39. The method of claim 27 wherein the host alters the firing sequence based on the fault condition.

40. The method of claim 27 wherein the host alters the laser-to-pixel mapping based on the fault condition.

41. The method of claim 27 further comprising reporting health status to a host that takes an action on the LiDAR transmitter in response to the health status.

42. A method for detecting a health condition in a light detection and ranging (LiDAR) transmitter, the method comprising:
a) generating a control signal that comprises an address and desired drive voltage information for a laser in a laser array;
b) determining a value for a health condition of the laser in the laser array;
c) storing the address and the value of the health condition if the value is outside a threshold range for functional safety; and
d) reporting the address and the fault condition to a host that takes an action on the LiDAR transmitter in response to the health condition.
